(19) United States
(12) Patent Application Publication
(10) Pub. No.: US 2007/0287209 A1
(43) Pub. Date: Dec. 13, 2007

(54) Method for manufacturing light-emitting device

(75) Inventor: Teruyuki Fujii, Kanagawa (JP)

Correspondence Address: COOK, ALEX, McFARRON, MANZO, CUMMINGS & MEHLER,;LTD., SUITE 2850, 200 WEST ADAMS STREET, CHICAGO, IL, 60606, US

(73) Assignee: Semiconductor Energy Laboratory Co., Ltd.

(21) Appl. No.: 11/788,298

(22) Filed: Apr. 19, 2007

(30) Foreign Application Priority Data
Apr. 28, 2006 (JP) 2006-127012

(51) Int. Cl. H01L 21/02

(52) U.S. Cl. 438/26; 257/E21.002

(57) ABSTRACT

To obtain a long-life light-emitting device. The invention relates to a manufacturing method of a light-emitting device, including forming a first electrode over a substrate, forming a partition wall using a resin material over the substrate and the first electrode, holding the partition wall for a first time period by hour at a first temperature which is lower than the curing temperature, holding the partition wall for a second time period by hour at a second temperature which is higher than the curing temperature after holding at the first temperature, forming a light-emitting layer over the partition wall so as to be in contact with the first electrode after holding at the second temperature, and forming a second electrode over the light-emitting layer. Accordingly, moisture or gas generation from a partition wall can be suppressed, and a life of a light-emitting element can be prolonged.

### BACKGROUND OF THE INVENTION

1. Field of the Invention

The present invention relates to a light-emitting device and a method for manufacturing the light-emitting device.

2. Description of the Related Art

A light-emitting device using a light-emitting element which includes a light-emitting layer between a pair of electrodes and emits light by supplying a current between the electrodes has been developed. Such a light-emitting device is advantageous for reduction in thickness and weight as compared to another display device which is called a thin display device, and visibility is high because it is self-luminous type, and response speed is also high. Therefore, development thereof has been actively promoted as a next-generation display device and practical application thereof has been partially performed.

One reason why such a light-emitting device has been put into practical use just partially is a deterioration problem of a light-emitting element. A light-emitting element is deteriorated such that the luminance is decreased in accordance with accumulation of driven time even if the amount of current supplied thereto is constant. One of the reasons is that there have not been so many materials, structures, and combinations of them for manufacturing a light-emitting element in which the degree of the deterioration is acceptable as an actual product.

As an example of the light-emitting device described above, there is a light-emitting display device in which a light-emitting element in which a layer containing an organic material, an inorganic material, or a mixture of an organic material and an inorganic material exhibiting light emission called electroluminescence (hereinafter also referred to as EL) is interposed between electrodes, is connected to a thin film transistor (TFT).

An electroluminescence element (an EL element) can display a vivid and colorful image because light emission at high luminance can be realized. Light emission obtained from the light-emitting element is as bright as, for example, a luminance of 100 to 1000 cd/m². The light-emitting display device is advantageous in that response is fast and the display device can be reduced in thickness and weight because it is self-luminous type. A light-emitting element utilizing electroluminescence which can be applied in the present invention is distinguished by whether a light-emitting material is an organic compound or an inorganic compound; in usual, the former is called an organic EL element and the latter is called an inorganic EL element.

As a material for partitioning pixels each including an EL element (hereinafter referred to as a partition wall), a resin material is used (Reference 1: Japanese Published Patent Application No. 2000-294378). Moisture, gas, or the like generated from the resin material is considered as one cause of deterioration of the light-emitting properties of an EL element, particularly an organic EL element. Therefore, before an EL material is evaporated, a substrate is heated at a temperature of approximately 150 to 300° C. in the air or in vacuum to be dried.

### SUMMARY OF THE INVENTION

However, it was understood that a resin was not dried enough only by heating the resin at a temperature of approximately 150 to 300° C. in order to form a partition wall. In order to prevent deterioration of an EL element, it is necessary to reduce moisture, gas, or the like generated from the resin forming the partition wall.

The present invention focuses on the temperature in curing the resin; a step of vaporizing a solvent by heating at a first temperature of approximately 150° C. or more and 200° C. or less and a step of curing at a second temperature of approximately 300° C. or more and 350° C. or less are combined, thereby a resin with a reduced degassing yield is manufactured. By using such a resin for a partition wall, a long-life light-emitting device can be obtained.

The present invention relates to a method for manufacturing a light-emitting device, in which a first electrode is formed over a substrate, a partition wall is formed using a resin material over the substrate and the first electrode, the partition wall is held for a first time period at a first temperature which is lower than the curing temperature, the partition wall is held for a second time period at a second temperature which is higher than the curing temperature after holding at the first temperature, a light-emitting layer is formed over the partition wall and the first electrode after holding at the second temperature, and a second electrode is formed over the light-emitting layer.

In the present invention, the resin material is polyimide or polybenzoxazole.

In the present invention, the light-emitting layer is an organic compound.

In the present invention, the light-emitting layer is an inorganic compound.

In the present invention, the first temperature is 150° C. or higher and 200° C. or lower.

In the present invention, the second temperature is 300° C. or higher and 350° C. or lower.

Note that in this specification, a semiconductor device means any element or device which functions utilizing a semiconductor, and includes in its category an electro-optic device including a light-emitting device or the like including a semiconductor element and electronic equipment mounting the electro-optic device.

By the present invention, generation of gas, moisture, or the like from a resin forming a partition wall can be suppressed so that an adverse effect on a light-emitting layer of an EL element can be suppressed. Consequently, life of not only an EL element but also a light-emitting device or a semiconductor device including the EL element can be prolonged, and reliability can also be improved.

### BRIEF DESCRIPTION OF THE DRAWINGS

FIGS. 1A to 1D are diagrams showing a semiconductor device of the present invention.

FIG. 2 is a graph showing a manufacturing process of a semiconductor device of the present invention.

FIG. 3 is a diagram showing a manufacturing process of a semiconductor device of the present invention.

FIGS. 4A to 4D are diagrams showing a manufacturing process of a semiconductor device of the present invention.

FIGS. 5A to 5C are diagrams showing a manufacturing process of a semiconductor device of the present invention.

FIGS. 6A to 6C are diagrams showing a manufacturing process of a semiconductor device of the present invention.

FIGS. 7A and 7B are diagrams showing a manufacturing process of a semiconductor device of the present invention.

FIGS. 8A and 8B are diagrams showing a manufacturing process of a semiconductor device of the present invention.

FIGS. 9A and 9B are diagrams showing a manufacturing process of a semiconductor device of the present invention.

FIG. 10 is a diagram showing a manufacturing process of a semiconductor device of the present invention.

FIG. 11 is a diagram showing a manufacturing process of a semiconductor device of the present invention.

FIG. 12 is a diagram showing a manufacturing process of a semiconductor device of the present invention.

FIG. 13A to 13C are diagrams each showing a manufacturing process of a semiconductor device of the present invention.

FIG. 14A to 14C are diagrams each showing a manufacturing process of a semiconductor device of the present invention.

FIG. 15 is a diagram showing a manufacturing process of an EL module of the present invention.

FIG. 16 is a block diagram showing a structure of a receptor of the present invention.

FIGS. 17A and 17B are diagrams each showing an example of electronic equipment to which the present invention is applied.

FIG. 18 is a diagram showing a manufacturing process of a module of the present invention.

FIG. 19 is a diagram showing a manufacturing process of a module of the present invention.

FIG. 20 is a diagram showing an example of electronic equipment to which the present invention is applied.

FIGS. 21A to 21E are diagrams each showing an example of electronic equipment to which the present invention is applied.

FIG. 22 is a graph showing measurement results of a light-emitting element of the present invention.

FIG. 23 is a graph showing measurement results of a light-emitting element of the present invention.

FIG. 24 is a graph showing measurement results of a light-emitting element of the present invention.

FIG. 25 is a graph showing measurement results of a light-emitting element of the present invention.

FIG. 26 is a graph showing measurement results of a light-emitting element of the present invention.

FIG. 27 is a graph showing measurement results of a light-emitting element of the present invention.

FIG. 28 is a graph showing measurement results of a light-emitting element of the present invention.

FIG. 29 is a graph showing measurement results of a light-emitting element of the present invention.

FIG. 30 is a graph showing measurement results of a light-emitting element of the present invention.

FIG. 31 is a graph showing measurement results of a light-emitting element of the present invention.

FIG. 32 is a graph showing measurement results of a light-emitting element of the present invention.

FIG. 33 is a graph showing measurement results of a light-emitting element of the present invention.

FIG. 34 is a graph showing measurement results of a light-emitting element of the present invention.

FIG. 35 is a graph showing measurement results of a light-emitting element of the present invention.

FIG. 36 is a graph showing measurement results of a light-emitting element of the present invention.

FIG. 37 is a graph showing measurement results of a light-emitting element of the present invention.

FIG. 38 is a graph showing measurement results of a light-emitting element of the present invention.

FIG. 39 is a graph showing measurement results of a light-emitting element of the present invention.

FIG. 40 is a graph showing measurement results of a light-emitting element of the present invention.

FIG. 41 is a graph showing measurement results of a light-emitting element of the present invention.

FIG. 42 is a graph showing measurement results of a light-emitting element of the present invention.

FIG. 43 is a graph showing measurement results of a light-emitting element of the present invention.

FIG. 44 is a graph showing measurement results of a light-emitting element of the present invention.

FIG. 45 is a graph showing measurement results of a light-emitting element of the present invention.

### DETAILED DESCRIPTION OF THE INVENTION

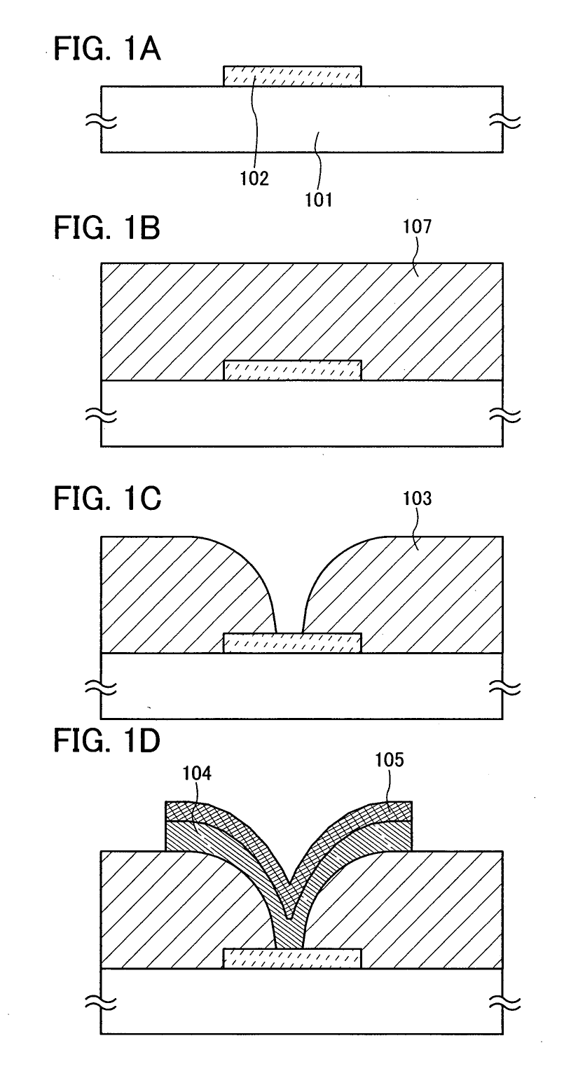

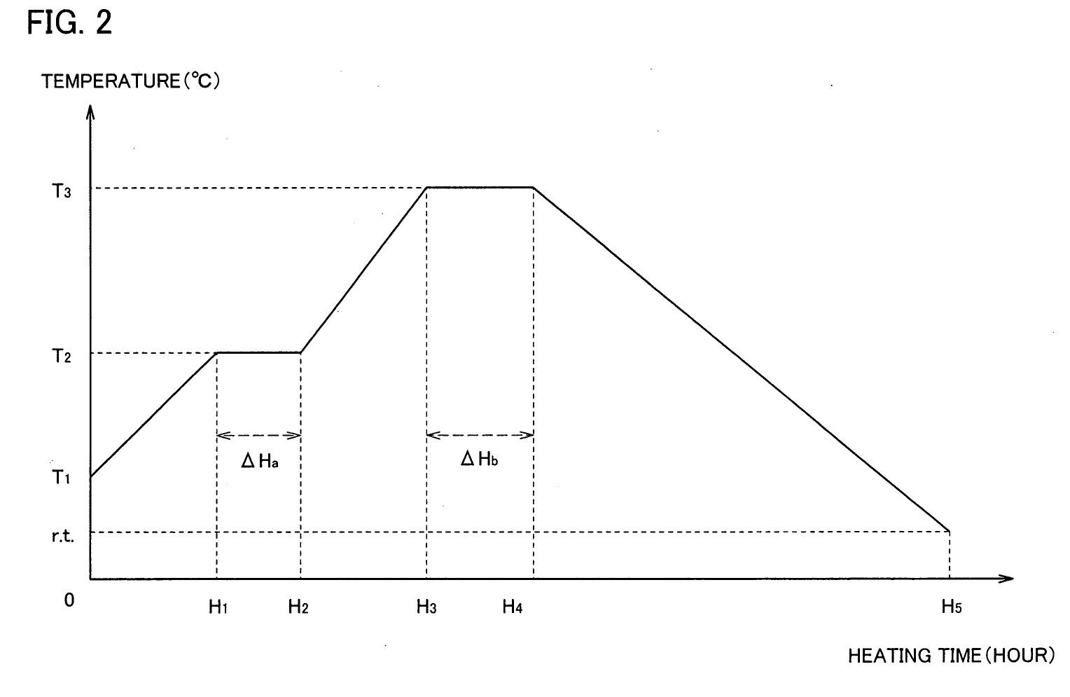

An embodiment mode of the present invention is described with reference to FIGS. 1A to 1D and 2. Note that in FIG. 2, T₁ to T₃ denote temperatures and H₁ to H₅ denote time periods. In addition, ΔHₐ and ΔH_{b} denote time periods from H₁ to H₂ and from H₃ to H₄, respectively.

Although the present invention is fully described by way of an embodiment mode and embodiments with reference to the accompanying drawings, it is to be understood that various changes and modifications will be apparent to those skilled in the art. Therefore, unless such changes and modifications depart from the spirit and scope of the present invention, they should be construed as being included therein. Note that in each structure of the present invention described below, reference numerals are used in common through the drawings.

First, a first electrode 102 is formed over a substrate 101 (see FIG. 1A). For the substrate 101, glass, quartz, or the like can be used. Note that a base insulating film may also be formed over the substrate 101 before the first electrode 102 is formed.

For the first electrode 102 and a second electrode 105 which is formed in a later step, a metal, an alloy, a conductive compound, a mixture thereof, or the like can be used. Specifically, indium oxide-tin oxide (Indium Tin Oxide which is also called ITO), indium oxide-tin oxide containing silicon or silicon oxide, indium oxide-zinc oxide (Indium Zinc Oxide which is also called IZO), tungsten oxide-indium oxide containing tungsten oxide and zinc oxide, and the like can be given as examples. Such a conductive metal oxide film is usually formed by sputtering. For example, indium oxide-zinc oxide (IZO) can be formed by sputtering using a target in which zinc oxide is added at 1 to 20 wt % with respect to indium oxide. Tungsten oxide-indium oxide containing zinc oxide can be formed by sputtering using a target in which tungsten oxide is added at 0.5 to 5 wt % and zinc oxide is added at 0.1 to 1 wt % with respect to indium oxide.

Alternatively, for the first electrode 102 and the second electrode 105, aluminum (Al), silver (Ag), gold (Au), platinum (Pt), nickel (Ni), tungsten (W), chromium (Cr), molybdenum (Mo), iron (Fe), cobalt (Co), copper (Cu), palladium (Pd), nitride of a metal material (e.g., titanium nitride: TiN), or the like can be used.

Note that in the case where at least one of the first electrode 102 and the second electrode 105 is formed as a light-transmitting electrode, even a material of which has low transmittance of visible light can be used for the light-transmitting electrode by forming a film thereof with a thickness of approximately 1 to 50 nm, preferably approximately 5 to 20 nm. Note that each electrode can also be formed by using vacuum evaporation, CVD, or a sol-gel method as well as sputtering.

Note that since light emission is taken outside through the first electrode 102 or the second electrode 105, it is necessary that at least one of the first electrode 102 and the second electrode 105 is formed of a light-transmitting material. In addition, it is preferable that each material be selected such that a work function of the first electrode 102 becomes larger than that of the second electrode 105. Further, each of the first electrode 102 and the second electrode 105 is not necessarily one layer; two or more layers may also be used.

Next, a resin material 107 is formed over the substrate 101 and the first electrode 102 (see FIG. 1B). In this embodiment mode, polyimide is stacked as the resin material 107 with a spinner. As the resin material 107, polybenzoxazole or the like can also be used as well as polyimide.

Next, the formed resin material 107 is shaped into a predetermined shape to form a partition wall 103 (see FIG. 1C). As a method for shaping into the predetermined shape, a method of providing photosensitivity for the resin material like a resist material is preferable. In the case where the resin does not have photosensitivity, wet or dry etching may also be performed using a resist material.

Next, the substrate 101 is disposed into a hot plate or an oven to perform a step of heating the partition wall 103. As shown in FIG. 2, the temperature is raised from T₁ to T₂ which is lower than the curing temperature. In this embodiment mode, T₁ is set at 100° C. and T₂ is set at 150 to 200° C.

Then, the substrate 101 is held at the temperature of T₂ for a time period of ΔHₐ. In this embodiment mode, ΔHₐ is set at 0.5 hour.

Next, the temperature is raised again from T₂ to T₃, and the substrate 101 is held at the temperature of T₃ which is higher than the curing temperature for a time period of ΔH_{b}. In this embodiment mode, T₃ is set at 300 to 350° C. and ΔH_{b} is set at 0.5 hour.

Next, the substrate 101 is cooled to room temperature (r.t.), and is taken out from the hot plate or the oven. Alternatively, the substrate 101 may be taken out from the hot plate or the oven when the temperature is 100 to 200° C., e.g., 150° C., and disposed at room temperature to be cooled gradually.

As described above, by baking at a temperature which is higher than the usual curing temperature, such as T₃ and by holding at the temperature of T₂ which is lower than the usual curing temperature for a time period of ΔHₐ, a solvent contained in the resin material 107 forming the partition wall 103 can be removed and moisture generation from the resin material 107 forming the partition wall 103 can also be suppressed. Consequently, a partition wall with a reduced degassing yield and reduced moisture evaporation can be obtained. Accordingly, an advantage such that lives of an EL element and a light-emitting device including the EL element can be prolonged can be obtained.

Next, a light-emitting layer 104 is formed over the partition wall 103 and the first electrode 102. In this embodiment mode, an organic compound is used for the light-emitting layer 104.

As the organic compound of the light-emitting layer 104, the following material can be used. For example, as a light-emitting material which emits red light, Alq₃:DCM, Alq₃:rubrene:BisDCJTM, or the like is used. As a light-emitting material which emits green light, Alq₃:DMQD (N,N′-dimethylquinacridone), Alq₃:coumarin 6, or the like is used. As a light-emitting material which emits blue light, α-NPD, tBu-DNA, or the like is used.

Further, the present invention can also be applied to the case where an inorganic compound is used for the light-emitting layer 104. Since moisture generation from the partition wall 103 is suppressed by the present invention, a long-life inorganic EL element can be obtained.

An inorganic EL element using an inorganic compound as a light-emitting material is classified into a dispersion type inorganic EL element and a thin-film type inorganic EL element, depending on its element structure. The former and the latter are different in that the former has an electroluminescence layer where particles of the light-emitting material are dispersed in a binder whereas the latter has an electroluminescence layer formed of a thin film of the light-emitting material. However, the former and the latter have in common that electrons accelerated by a high electric field are necessary. Note that, as a mechanism of light emission that is obtained, there are donor-acceptor recombination type light emission that utilizes a donor level and an acceptor level, and localized type light emission that utilizes inner-shell electron transition of a metal ion. In usual, in many cases, a dispersion type inorganic EL element exhibits donor-acceptor recombination type light emission, and a thin-film type inorganic EL element exhibits localized type light emission.

The light-emitting material which can be used in the present invention includes a host material and an impurity element to be a light-emission center. By changing the impurity element that is contained, light emission of various colors can be obtained. As a manufacturing method of the light-emitting material, various methods such as a solid phase method and a liquid phase method (a coprecipitation method) can be used. Further, an evaporative decomposition method, a double decomposition method, a method by heat decomposition reaction of a precursor, a reversed micelle method, a method in which such a method is combined with high temperature baking, a liquid phase method such as a lyophilization method, or the like can also be used.

The solid phase method is a method in which a host material, and an impurity element or a compound containing an impurity element are weighed, mixed in a mortar, heated and baked in an electric furnace to be reacted, thereby containing the impurity element in the host material. The baking temperature is preferably 700 to 1500° C. This is because the solid reaction does not progress when the temperature is too low, whereas the host material is decomposed when the temperature is too high. Note that although baking may be performed in a powder state, it is preferable to perform baking in a pellet state. Although baking is necessarily performed at a comparatively high temperature, the solid phase method is easy; thus, the solid phase method is suitable for mass production because of high productivity.

The liquid phase method (a coprecipitation method) is a method in which a host material or a compound containing a host material is reacted with an impurity element or a compound containing an impurity element in a solution, dried, and then baked. Particles of the light-emitting material are distributed uniformly, and the reaction can progress even when the grain size is small and the baking temperature is low.

As the host material used for the light-emitting material, sulfide, oxide, or nitride can be used. As sulfide, for example, zinc sulfide (ZnS), cadmium sulfide (CdS), calcium sulfide (CaS), yttrium sulfide (Y₂S₃), gallium sulfide (Ga₂S₃), strontium sulfide (SrS), barium sulfide (BaS), or the like can be used. As oxide, for example, zinc oxide (ZnO), yttrium oxide (Y₂O₃), or the like can be used. As nitride, for example, aluminum nitride (AlN), gallium nitride (GaN), indium nitride (InN), or the like can be used. Further, zinc selenide (ZnSe), zinc telluride (ZnTe), or the like can also be used. Alternatively, a ternary mixed crystal such as calcium sulfide-gallium (CaGa₂S₄), strontium sulfide-gallium (SrGa₂S₄), or barium sulfide-gallium (BaGa₂S₄) may also be used.

As the light-emission center of localized type light emission, manganese (Mn), copper (Cu), samarium (Sm), terbium (Tb), erbium (Er), thulium (Tm), europium (Eu), cerium (Ce), praseodymium (Pr), or the like can be used. Note that a halogen element such as fluorine (F) or chlorine (Cl) may be added as charge compensation.

On the other hand, as the light-emission center of donor-acceptor recombination type light emission, a light-emitting material containing a first impurity element which forms a donor level and a second impurity element which forms an acceptor level can be used. As the first impurity element, for example, fluorine (F), chlorine (Cl), aluminum (Al), or the like can be used. As the second impurity element, for example, copper (Cu), silver (Ag), or the like can be used.

In the case of synthesizing the light-emitting material of donor-acceptor recombination type light emission by the solid phase method, the host material, the first impurity element or a compound containing the first impurity element, and the second impurity element or a compound containing the second impurity element are each measured, mixed in a mortar, heated and baked in an electric furnace. As the host material, any of the above described host materials can be used. As the first impurity element or the compound containing the first impurity element, for example, fluorine (F), chlorine (Cl), aluminum sulfate (Al₂S₃), or the like can be used. As the second impurity element or the compound containing the second impurity element, for example, copper (Cu), silver (Ag), copper sulfide (Cu₂S), silver sulfide (Ag₂S), or the like can be used. The baking temperature is preferably 700 to 1500° C. This is because the solid reaction does not progress when the temperature is too low, whereas the host material is decomposed when the temperature is too high. Note that although baking may be performed in a powder state, it is preferable to perform baking in a pellet state.

As the impurity element in the case of utilizing solid reaction, a compound containing the first impurity element and the second impurity element may be combined. In this case, since the impurity element is easily diffused and solid reaction progresses easily, a uniform light-emitting material can be obtained. Further, since an unnecessary impurity element does not enter, a light-emitting material having high purity can be obtained. As the compound containing the first impurity element and the second impurity element, for example, copper chloride (CuCl), silver chloride (AgCl), or the like can be used.

Note that the concentration of these impurity elements may be 0.01 to 10 atomic % with respect to the host material, and is preferably in the range of 0.05 to 5 atomic %.

In the case of a thin-film type inorganic EL element, a light-emitting layer is a layer containing the above light-emitting material, which can be formed by a vacuum evaporation method such as a resistance heating evaporation method or an electron beam evaporation (EB evaporation) method, a physical vapor deposition method (PVD) such as sputtering, a chemical vapor deposition method (CVD) such as an organic metal CVD method or a hydride transport low-pressure CVD method, an atomic layer epitaxy method (ALE), or the like.

Next, the second electrode 105 is formed over the light-emitting layer 104 (see FIG. 1D). A material and a manufacturing step of the second electrode 105 are as described above in manufacturing the first electrode 102.

In this manner, a light-emitting device is manufactured. In the light-emitting device of this embodiment, the light-emitting layer 104 is less affected because the degassing yield from the partition wall 103 is small. Consequently, a long-life light-emitting device can be obtained.

Note that this embodiment can be combined with any description of embodiments, if necessary.

### Embodiment 1

In this embodiment, changes in properties of polyimide depending on a baking condition were observed.

Polyimide (hereinafter abbreviated to PI) which is a resin having heat-resisting properties and insulation properties has been widely used with photosensitivity provided in a semiconductor field; in many cases, it is used as a partition wall for partitioning pixels in a light-emitting device including an EL element.

In this embodiment, heat-resisting properties and optical properties were evaluated in order to examine how much properties of PI depend on a baking condition.

As for the heat-resisting properties, a mass spectrum was measured by Thermal Desorption Spectroscopy (hereinafter called TDS) so that kinds and amounts of generated gases were weighed up.

Description is made below on the TDS measurement.

First, PI samples for the TDS measurement were manufactured in conditions shown in Table 1. Note that in this embodiment, a baking temperature corresponds to the temperature of T₃ in FIG. 2.

TABLE 1

| | Sample 1 | Sample 2 | Sample 3 | Sample 4 |
|---|---|---|---|---|
| Partition | Polyimide | | | |
| material | | | | |
| Prebake | 122° C. × 120 sec | | | |
| Baking | 260° C. × 1 h | 280° C. × 1 h | 300° C. × | 320° C. × |
| | | | 1 h | 1 h |
| Thickness after | 1.38 μm | 1.34 μm | 1.32 μm | 1.26 μm |
| baking | | | | |

| | |
|---|---|
| Sample size | 10 mm × 10 mm |
| Base substrate | Glass (EAGLE2000) |

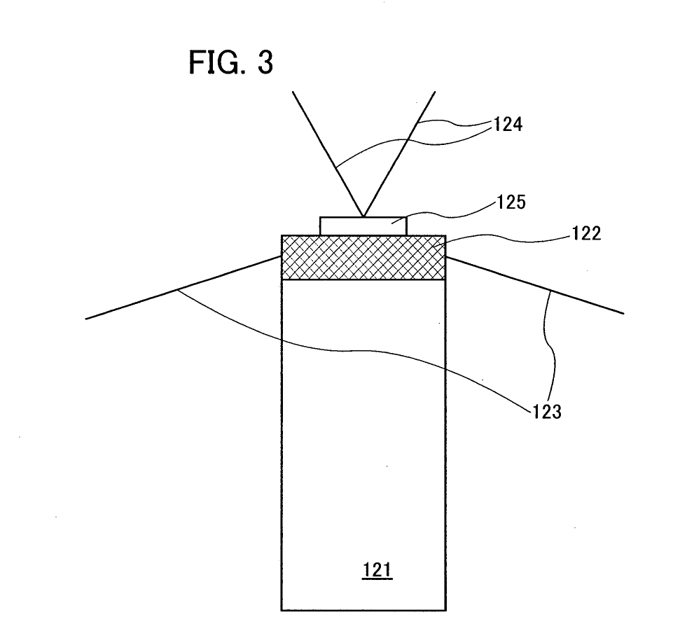

A schematic diagram of a sample stage of measurement equipment of TDS is FIG. 3. There is a quartz column 121 below a sample stage 122, and the temperature is controlled by an infrared ray through the quartz column 121. A sample 125 is disposed on the sample stage 122.

In the measurement equipment in FIG. 3, a stage temperature T_{ST} and a sample surface temperature T_{SP} are monitored with a thermocouple 123 and a thermocouple 124 respectively. In vacuum, since the thermal conductivity is remarkably reduced, T_{ST} and T_{SP} are different by approximately 100 to 300° C. A chamber is kept at a pressure of 10⁻⁸ to 10⁻⁷ Pa, and the pressure is increased to near 10⁻⁵ Pa only when a gas is generated by heating the sample. The generated gas is converted into a mass spectrum through componential analysis with QMS (Quardrupole Mass Spectrometer).

A TDS spectrum was measured in conditions shown in Table 2 with the measurement equipment shown in FIG. 3. Note that it was confirmed by preliminary measurement that there was no degassing consituent with a mass number of 100 or more.

TABLE 2

| | |
|---|---|
| Temperature | Room temperature to 700° C. |
| | (stage temperature T_{ST}) |
| Raising rate | 0.5° C./sec |
| | (stage temperature T_{ST}) |
| Pressure in | Measurement start at equal to or |
| chamber | less than 1.1 × 10⁻⁷ Pa |
| Mass number of | 0 to 100 |
| measurement | |
| SEM voltage | 1100 V |

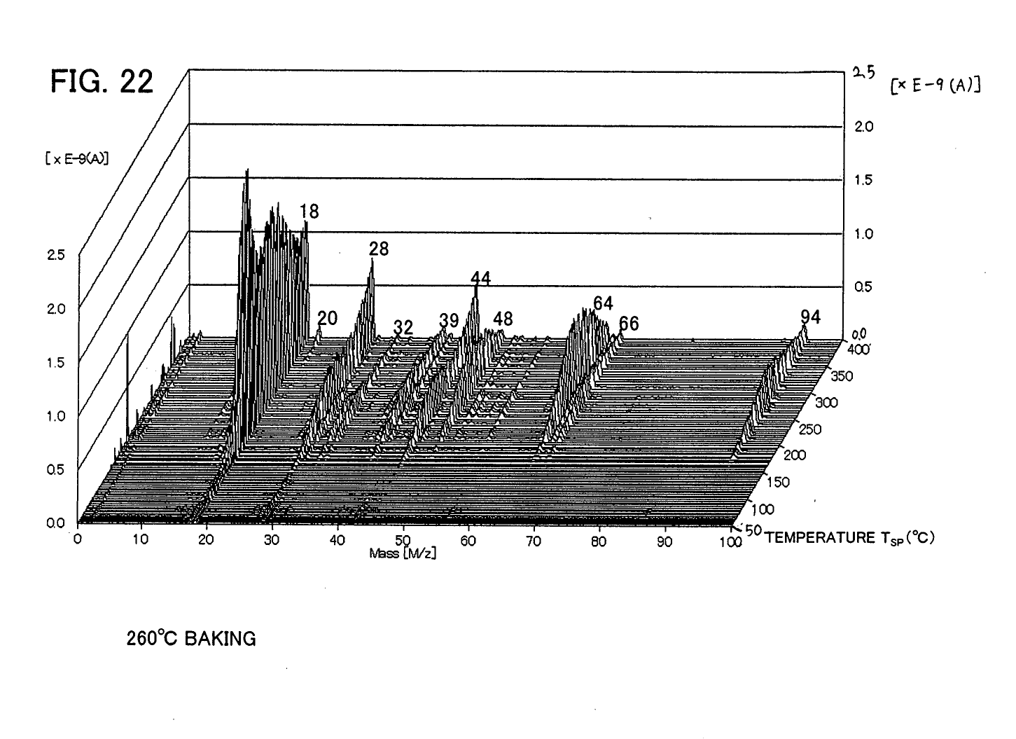

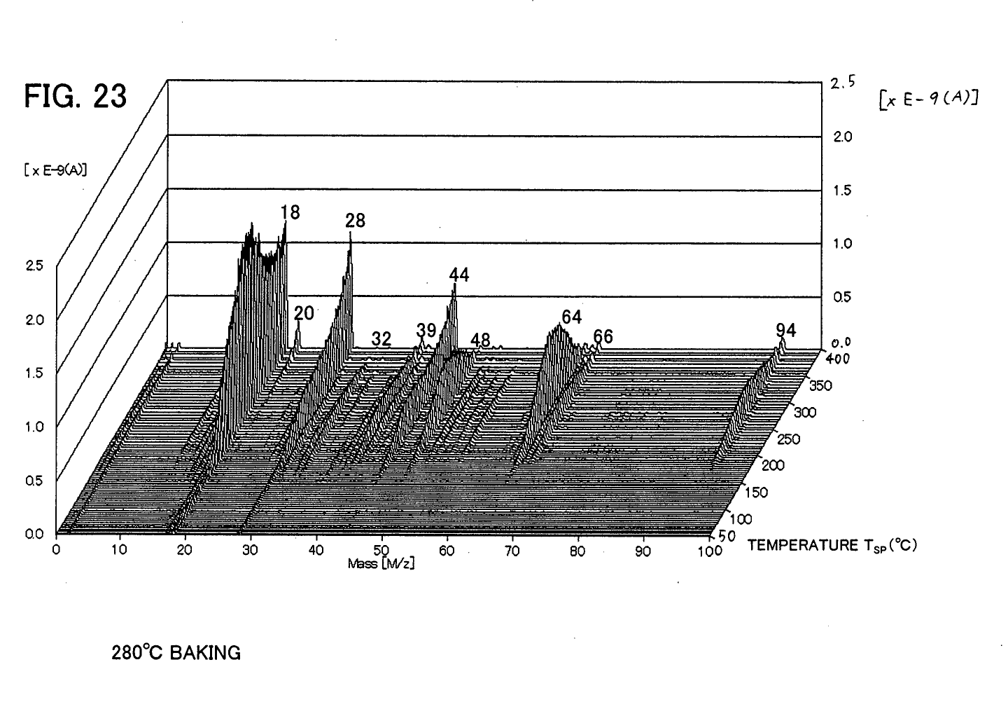

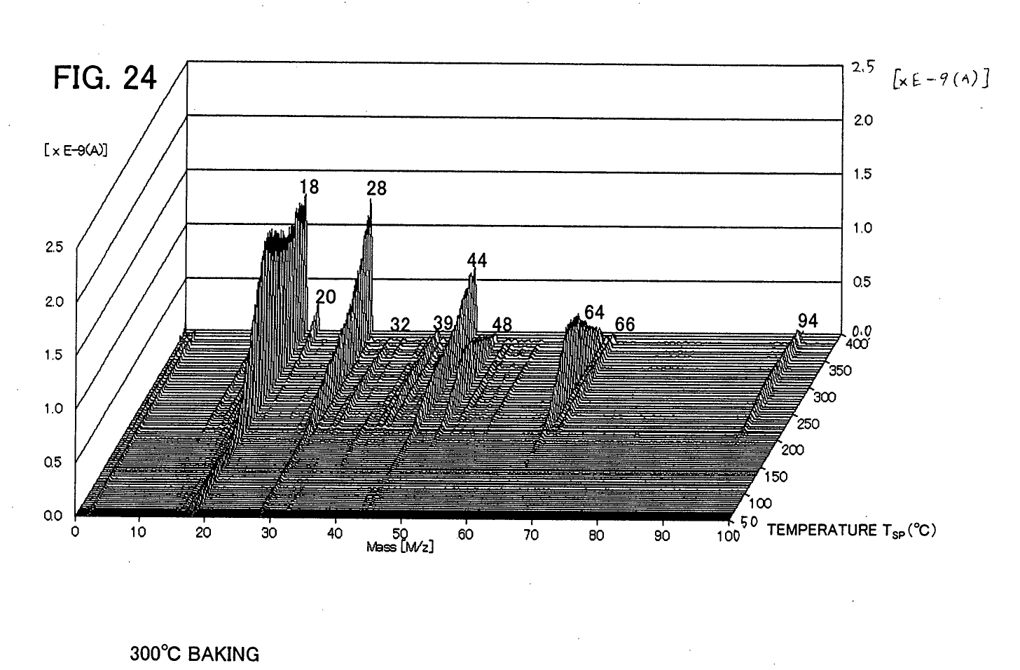

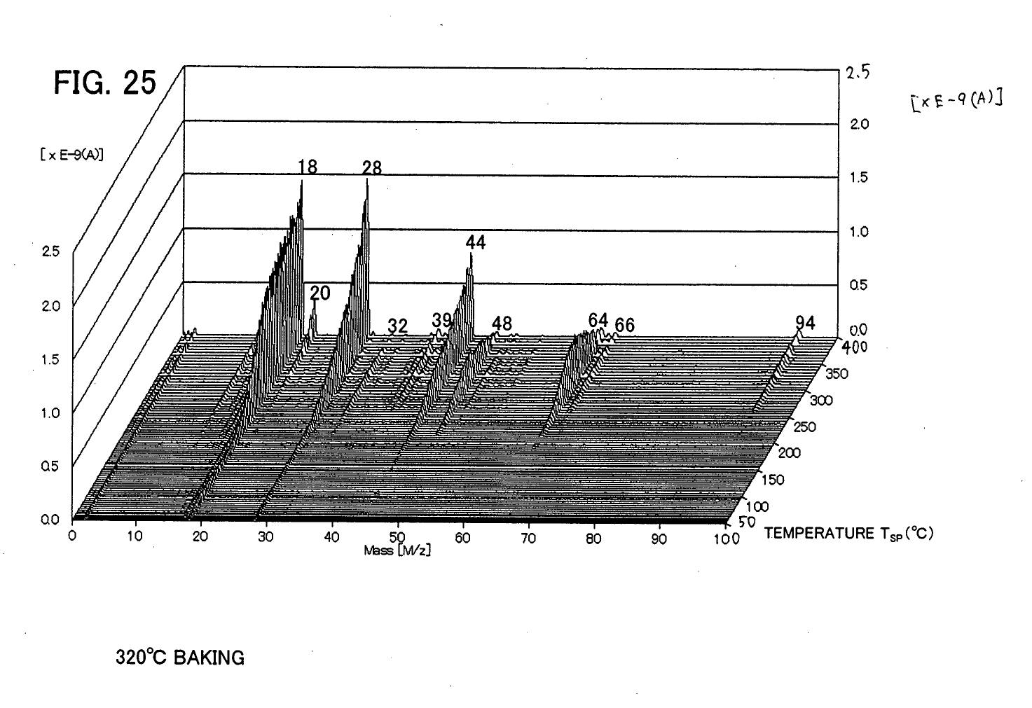

Results of Scan measurement are shown in FIGS. 22 to 25. A temperature axis indicates the temperature T_{SP} obtained by monitoring a surface of the sample 125 with the thermocouple 124, and each number marked at peaks in the spectra denotes corresponding Mass Number.

From comparison among the TDS spectra of FIGS. 22 to 25, it was understood that the intensity of each spectrum peak or the shape in the temperature axis direction changed depending on the baking temperature. As an overall trend, it seems that the TDS spectrum of the sample baked at a high temperature is shifted toward the high temperature side of the temperature axis as compared with that of the sample baked at a low temperature. In particular, as for H₂O (Mass Number: 18), there are two desorption peaks in a low temperature region and a high temperature region and the degassing yield is high even in a comparatively low temperature region of a temperature of 200° C. or less in the sample baked at a low temperature, whereas there is only a degassing yield only in the high temperature region in the sample baked at a high temperature.

Estimation of constituents corresponding to the spectrum peaks and characteristics in change of degassing yield depending on the baking temperature are written up in Table 3.

TABLE 3

| | Estimation | | |
|---|---|---|---|
| Mass | of chemical | Estimation of generating | |
| number | species | mechanism | Degassing yield |
| 18 | H₂O | Moisture in film, thermal | Being decreased as baking |
| | | oxidation | temperature of sample is increased |
| 20 | HF | From fluorine compound in | Being increased as baking |
| | | PI | temperature of sample is increased |
| 28 | CO | Thermal decomposition | Being increased as baking |
| | | and thermal oxidation of PI | temperature of sample is increased |
| 32 | S, O₂ | From photosensitive agent | Being decreased as baking |
| | | (S) | temperature of sample is increased |
| 39 | not clear | not clear | Being decreased as baking |
| | | | temperature of sample is increased |
| 44 | CO₂ | Thermal decomposition | Being increased as baking |
| | | and thermal oxidation of PI | temperature of sample is increased |
| 48 | not clear | not clear | not clear |
| 64 | SO₂ | From photosensitive agent | Being decreased as baking |
| | | | temperature of sample is increased |
| 66 | not clear | not clear | Being decreased as baking |
| | | | temperature of sample is increased |
| 94 | C₄O₂N | Imide ring | Being decreased as baking |
| | | | temperature of sample is increased |

Note that when a mass spectrum of any molecule, it is detected almost always with a plurality of constituenTDSecomposed. For example, in the case of benzene, decomposed constituents (fragments) other than a constituent with a mass number of 78 corresponding to C₆H₆ are always detected, and an intensity ratio of them is fixed. Unless the detected intensity ratio of these fragment constituents completely agrees with a value listed in a literature, the constituents cannot be identified. Therefore, chemical species shown in Table 3 are just estimation and are not confirmed.

Note that, although as shown in Table 3, as for HF, CO, and CO₂, each degassing yield tends to be small in the low-temperature baked sample, which is considered important, just qualitative evaluation can be performed as for the baking temperature dependency only by reviewing spectrum data obtained from the above-described Scan measurement.

Therefore, MID (Multi-ion Detection) measurement which has a higher quantitativity was also performed in the same conditions. Described below are results of the MID measurement.

In the MID measurement, the measurement is performed to the constituents with the mass numbers of which degassing was confirmed in the TDS spectra of FIGS. 22 to 25, thereby measuring each degassing yield in accordance with temperature rising. Although the measurement was performed three-dimensionally in the Scan measurement shown in FIGS. 22 to 25, the measurement is performed two-dimensionally in the MID measurement. In the MID measurement as compared with the Scan measurement, although the measurable dimension is smaller (the number of measurable parameters is smaller), the accuracy is improved.

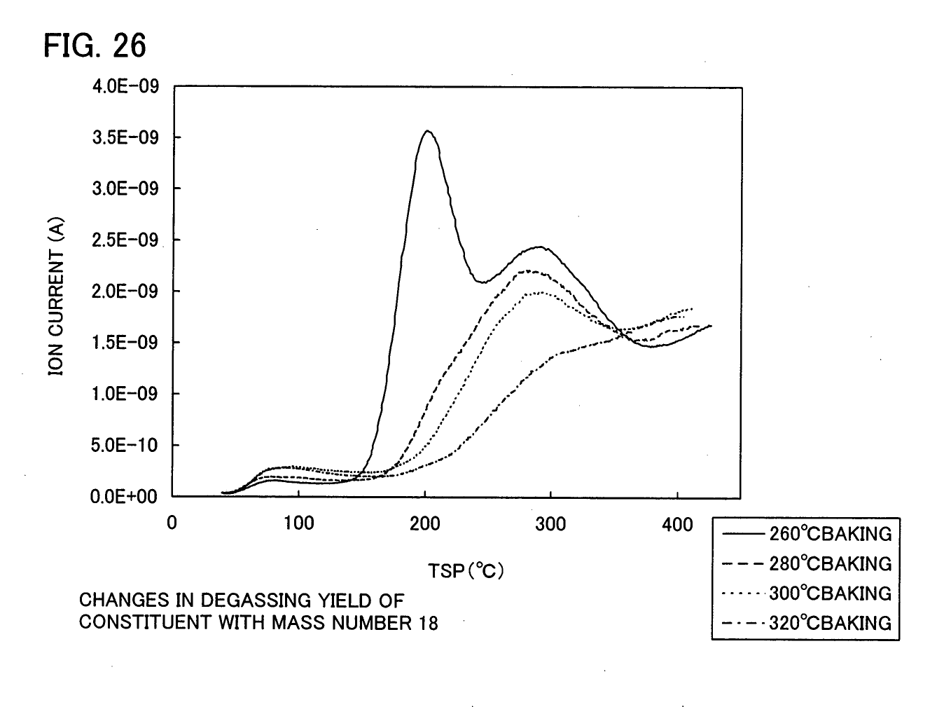

FIGS. 26 to 30 show results of the MID measurement of the constituents with mass numbers of 18, 20, 28, 64, and 94 respectively, and each show changes in degassing yield. Each change in degassing yield is obtained by plotting measured data as they are. As described above, it was considered that the constituent with the mass number of 18 was H₂O, the constituent with the mass number of 20 was HF, the constituent with the mass number of 28 was CO, the constituent with the mass number of 64 was SO₂, and the constituent with the mass number of 94 was C₄O₂N.

As shown in FIG. 26, the degassing yield of the constituent with the mass number of 18 (H₂O) is increased as the baking temperature of the sample is decreased. In particular, there is a first desorption constituent having a peak at approximately 200° C. in the sample baked at 260° C., which is largely different from the other samples. In addition, a peak of a second desorption constituent is at approximately 290° C.; however, the peak value is decreased as the baking temperature is increased, and the peak is almost disappeared in the sample baked at 320° C. As for the first desorption constituent, it can be assumed that a low-molecular-weight additive, of which rate of content is decreased as the baking temperature is increased, absorbs a water molecule with hydrogen bonding. It is assumed that the second desorption constituent is moisture absorbed in its film or a constituent generated by reacting a hydroxyl group (OH group) contained in its film with Hydrogen (H).

Further, if the film density is increased as the baking temperature is increased, it results in that the amount of moisture absorbed in the film is decreased as the baking temperature of the sample is increased. At any rate, from the aspect of moisture generation, it is preferable that the baking temperature be high.

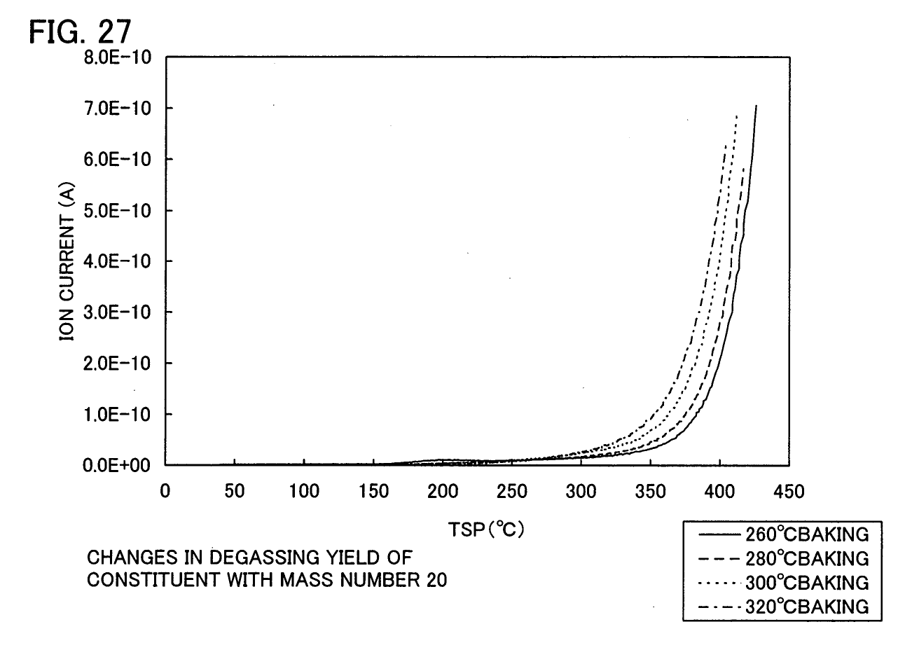

As shown in FIG. 27, the degassing yield of the constituent with the mass number of 20 (HF) is increased as the baking temperature of the sample is increased. A mechanism of HF generation is not clear. However, a fluorine compound is added into a resin material forming a partition wall in order to reduce the permittivity, and it is no doubt that HF generation is from this additive.

It can be considered that in the process of thermal decomposition, single fluorine (F) is not generated but is combined with peripheral hydrogen (H) to become HF which is more stable.

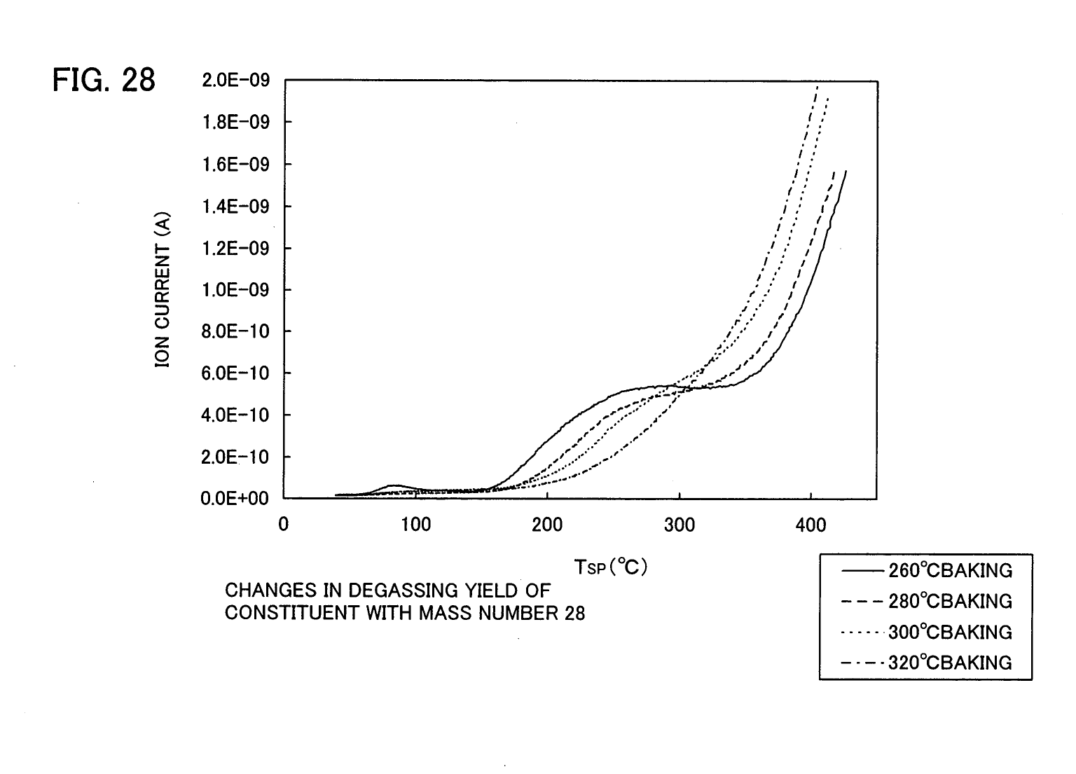

As shown in FIG. 28, the degassing yield of the constituent with the mass number of 28 (CO) is increased as the baking temperature of the sample is decreased in a low temperature region of 300° C. or less, whereas the degassing yield thereof is increased as the baking temperature of the sample is increased in a high temperature region of 300° C. or more. Although it can be considered that CO is generated both in the process of thermal decomposition of PI and from a low-molecular-weight constituent, why the characteristics shown in FIG. 28 are shown is not clear.

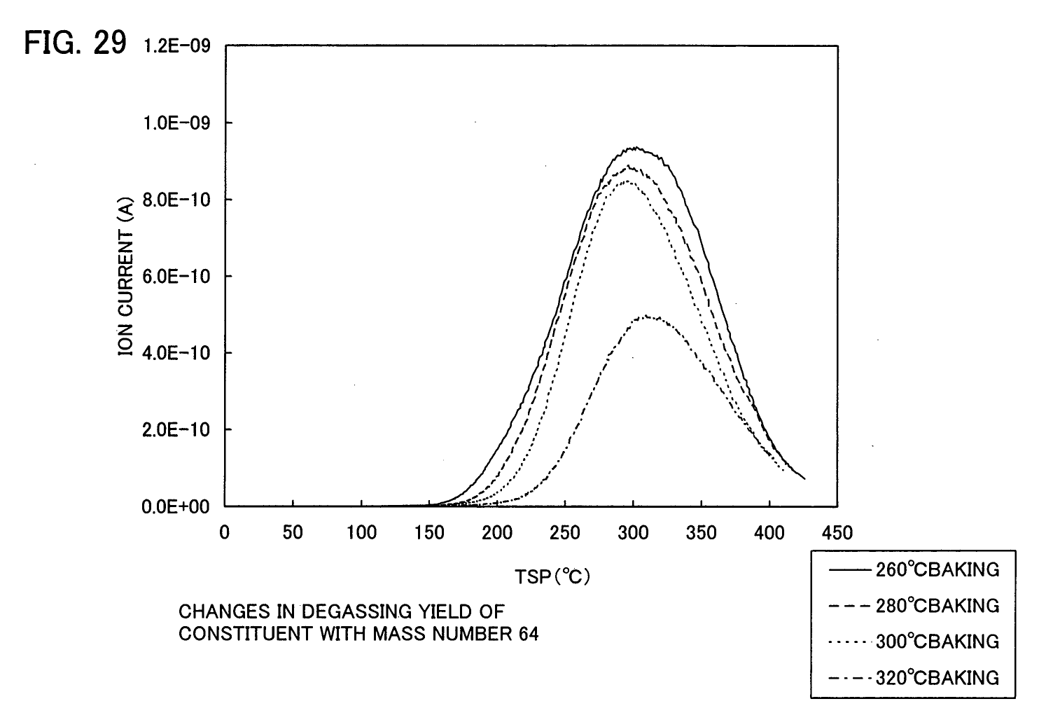

As shown in FIG. 29, the degassing yield of the constituent with the mass number of 64 (SO₂) is increased as the baking temperature of the sample is decreased. At any rate, each peak is at approximately 300° C., and the plot geometry is less different; however, there are large differences in the generation yield. It can be considered that the rate of content of a low-molecular-weight additive such as a photosensitive agent is decreased or a low-molecular-weight additive in a resin is difficult to be gotten out of the resin structurally as the baking temperature is increased. Therefore, as for the degassing of the constituent with the mass number of 64 (SO₂), it is preferable that the baking temperature be high.

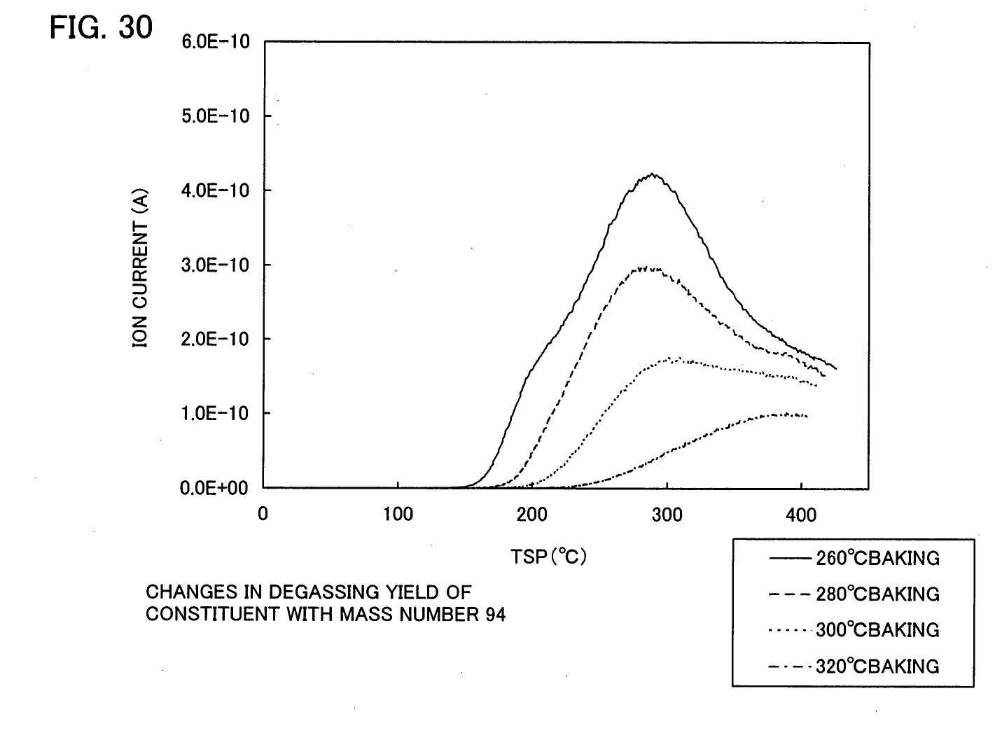

As shown in FIG. 30, the degassing yield of the constituent with the mass number of 94 (C₄O₂N) is also increased as the baking temperature of the sample is decreased. Although it cannot be determined that the constituent is an imide ring, there is a possibility of a difference in fundamental heat-resisting properties of a main component of polyimide.

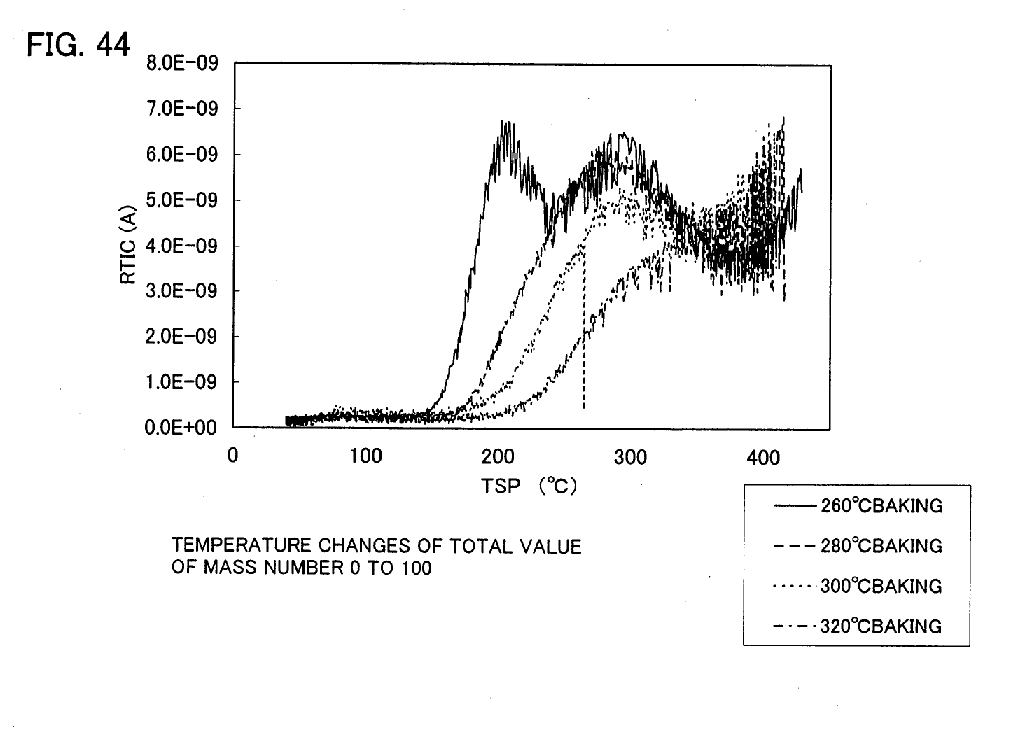

Further, FIG. 44 shows results of Scan measurement in the case where polyimide is used for a partition wall, in which a total value of constituents with the mass numbers 0 to 100 is plotted with respect to the sample surface temperature Tsp. A vertical axis indicates the sample surface temperature T_{SP}, whereas a horizontal axis indicates a Reconstruct Total Ion Current (RTIC) and equal to a total value of the constituents with the mass numbers 0 to 100.

From FIG. 44, it can be seen that although noise is large in the sample baked at 260° C., the degassing yield is decreased as the baking temperature is increased.

In summary, it can be concluded that properties such as the heat-resisting properties or the moisture-resisting properties can be improved as the baking temperature is increased in the range of 260° C. to 320° C.

### Embodiment 2

In this embodiment, changes in properties of polybenzoxazole (also called benzoxazole which is hereinafter abbreviated to PBO) depending on a baking condition were observed.

Polybenzoxazole is known to have higher heat-resisting properties, higher mechanical properties, lower hygroscopic properties, and a lower dielectric constant than polyimide (PI). Therefore, its application as a surface protective film or an interlayer insulating film instead of PI has been widened.

In this embodiment, heat-resisting properties were evaluated in order to examine how much properties of polybenzoxazole depend on a baking condition.

For evaluating the heat-resisting properties, Thermal Desorption Spectroscopy (TDS) was adopted. Mass spectra of gasses generated at vacuum heating were measured by this method so that kinds and amounts thereof were weighed up.

Samples for the TDS measurement were manufactured in conditions shown in Table 4. Note that in this embodiment, a baking temperature corresponds to the temperature of T₃ in FIG. 2.

TABLE 4

| | Sample 1 | Sample 2 | Sample 3 | Sample 4 |
|---|---|---|---|---|
| Partition | Polybenzoxazole | | | |
| material | | | | |
| Prebake | 125° C. × 4 min | | | |
| Baking | 280° C. × 1 h | 300° C. × 1 h | 320° C. × | 340° C. × |
| condition | | | 1 h | 1 h |
| Thickness after | 2.13 μm | 2.11 μm | 2.11 μm | 2.14 μm |
| baking | | | | |

| | |
|---|---|
| Sample size | 10 mm × 10 mm |
| Base substrate | Glass (EAGLE2000) |

In addition, the sample stage of TDS equipment shown in FIG. 3 is used similarly to Embodiment 1. The measurement method is also similar to Embodiment 1.

Measurement conditions of this embodiment are shown in Table 5.

TABLE 5

| | |
|---|---|
| Temperature | Room temperature to 700° C. |
| | (stage temperature T₁) |
| Raising rate | 0.5° C./sec |
| | (stage temperature T₁) |
| Pressure in | Measurement start at equal to or |
| chamber | less than 1.1 × 10⁻⁷ Pa |
| Mass number of | 0 to 100 |
| measurement | |

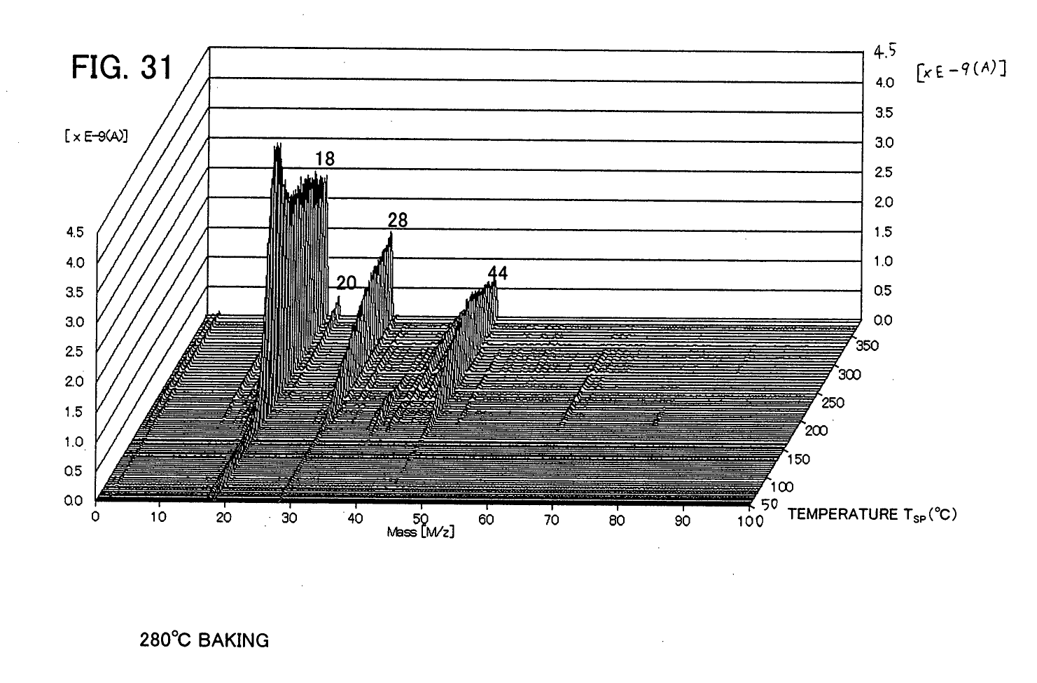

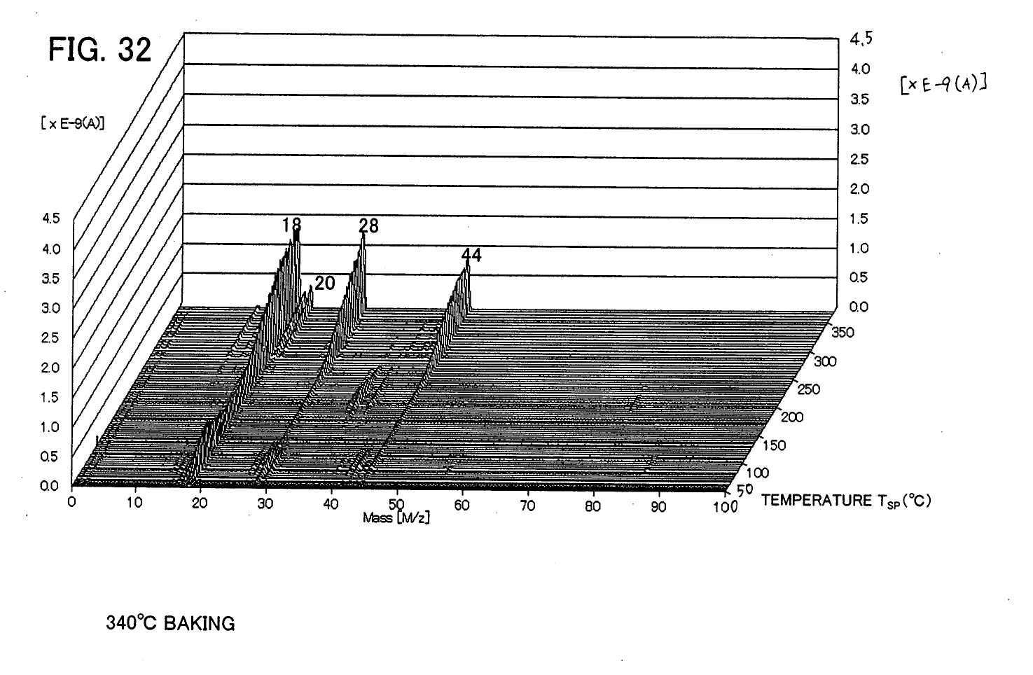

Results of Scan measurement are shown in FIGS. 31 and 32. A temperature axis indicates the temperature T_{SP} obtained by monitoring a surface of the sample with a thermocouple, and each number marked at peaks in the spectra denotes corresponding Mass Number.

From comparison among the spectra of FIGS. 31 and 32, it is understood that the intensity of each spectrum peak or the shape in the temperature axis direction changes depending on the baking temperature.

Estimation of constituents corresponding to the spectrum peaks and characteristics in change of degassing yield depending on the baking temperature in FIGS. 31 and 32 are written up in Table 6.

TABLE 6

| | Estimation | Estimation of | |
|---|---|---|---|
| Mass | of chemical | generating | |
| number | species | mechanism | Degassing yield |
| 18 | H₂O | Moisture in film, | Being decreased as baking |
| | | thermal oxidation | temperature of sample is |
| | | | increased |
| 20 | HF | From fluorine | Being increased as baking |
| | | compound in PBO | temperature of sample is |
| | | | increased |
| 28 | CO | Thermal | Being decreased as baking |
| | | decomposition and | temperature of sample is |
| | | thermal oxidation | increased |
| | | of PBO | |
| 44 | CO₂ | Thermal | Being decreased as baking |
| | | decomposition and | temperature of sample is |
| | | thermal oxidation | increased |
| | | of PBO | |

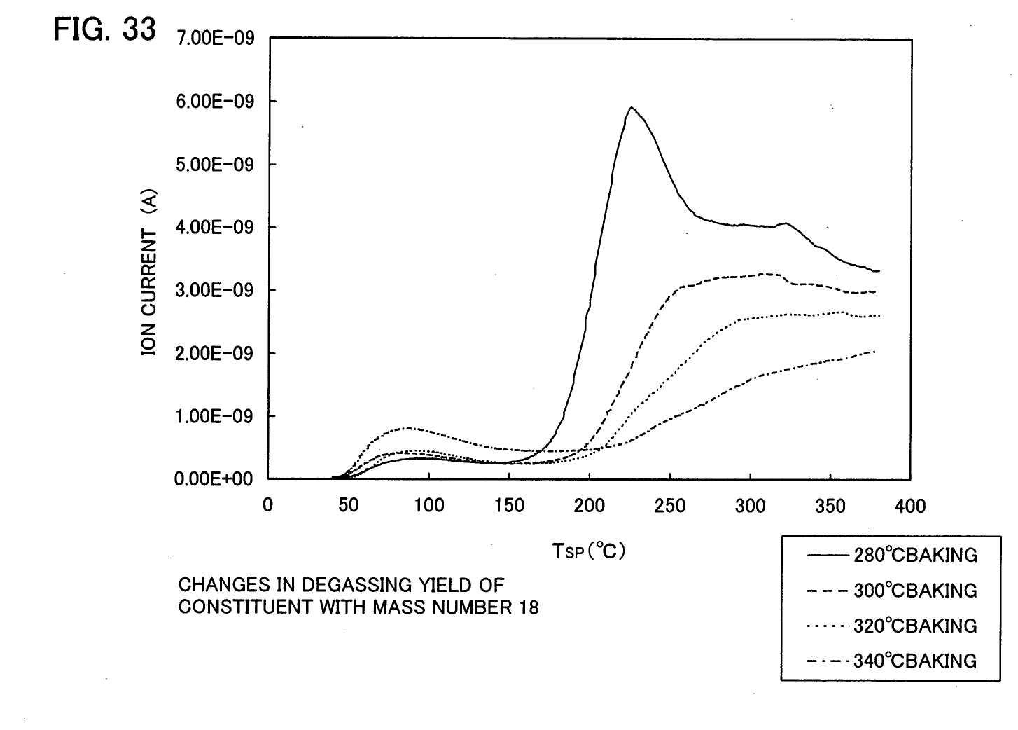

Next, MID measurement which has a higher quantitativity was performed in the same conditions. Results of the MID measurement are shown in FIGS. 33 to 36.

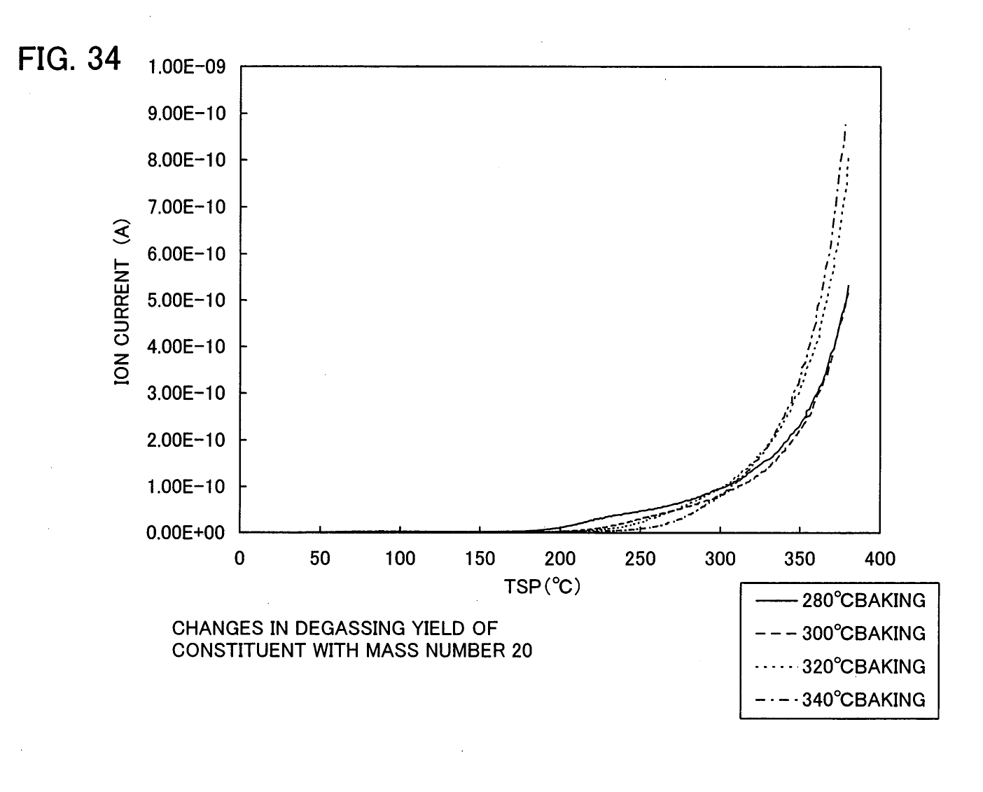

Dependency on the baking temperature of the constituent with the mass number of 18 shown in FIG. 33, and dependency on the baking temperature of the constituent with the mass number of 20 shown in FIG. 34 are similar to the results of polyimide (see Embodiment 1), by which it is suggested that each gas is generated from the same mechanism as that of polyimide.

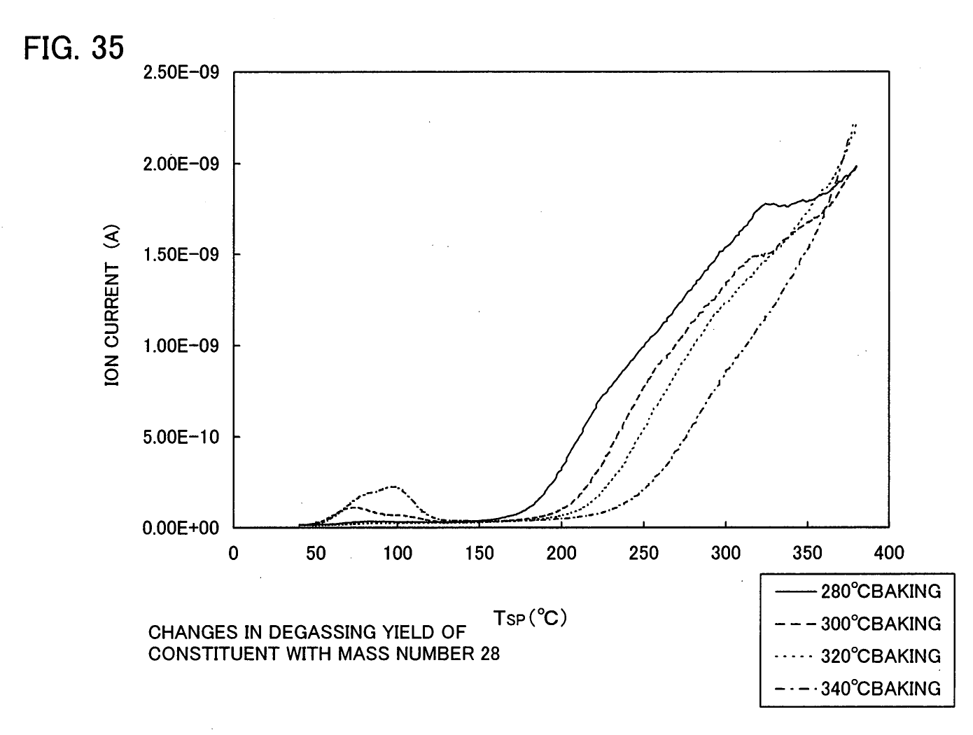

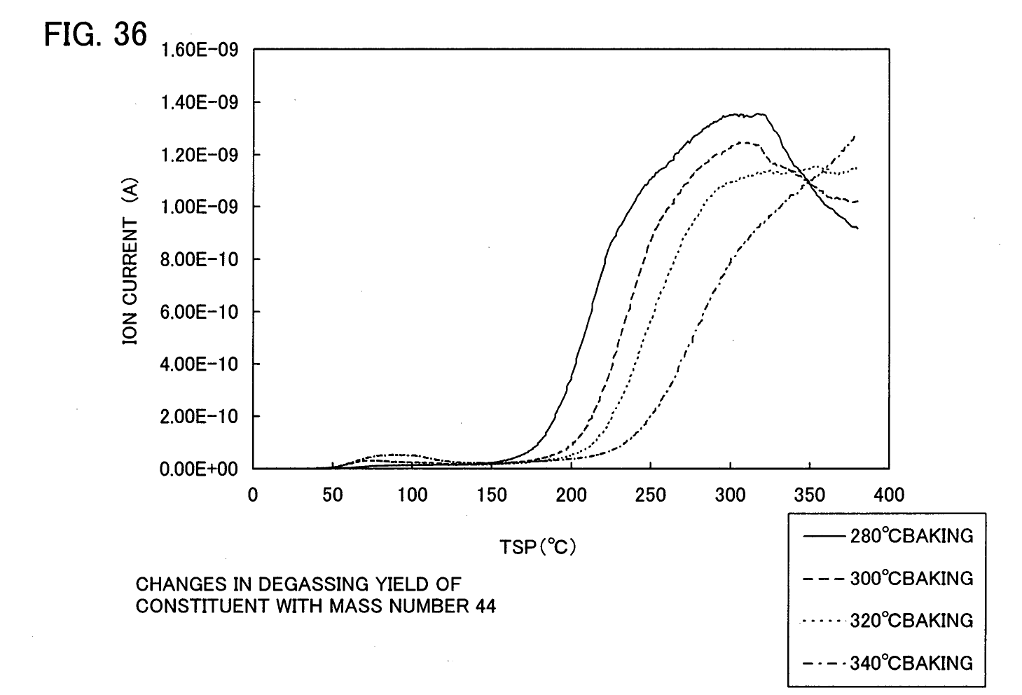

On the other hand, from FIGS. 35 and 36, there can be seen clear difference between the results of polyimide and polybenzoxazole in the constituents with the mass numbers of 28 and 44. It can be considered that the difference results from difference in molecular structure or an additive. Although it is difficult to estimate a mechanism of gas generation, the degassing yield tends to be remarkably reduced as the baking temperature is increased in the constituents with the mass numbers of 28 and 44 in polybenzoxazole, so that the heat-resisting properties are remarkably improved as the baking temperature is increased. This is because the film quality (e.g., the film density or the amount of a low-molecular-weight constituent) changes depending on the baking temperature.

Thus, in this embodiment mode, TDS measurement was performed by baking polybenzoxazole at four conditions of temperature in the range of 280° C. to 340° C. Consequently, it was understood that the degassing yield tended to be smaller as the baking temperature of polybenzoxazole was higher.

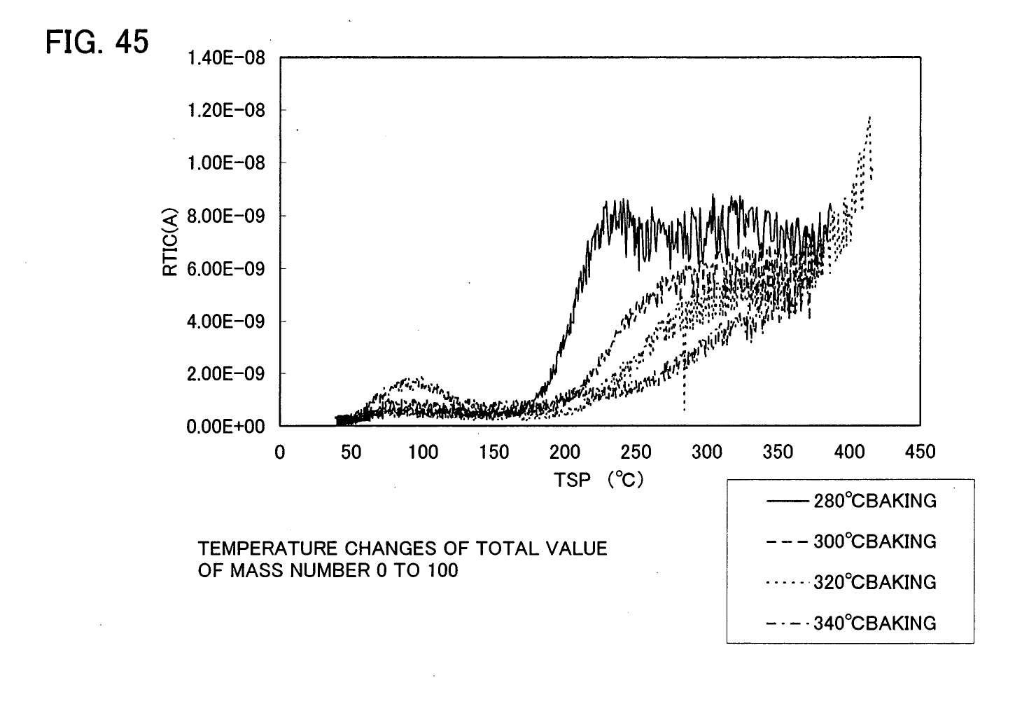

Further, FIG. 45 shows results of Scan measurement in the case where polybenzoxazole is used for a partition wall, in which a total value of constituents with mass numbers 0 to 100 is plotted with respect to the sample surface temperature T_{SP}. A horizontal axis indicates the sample surface temperature T_{SP}, whereas a vertical axis indicates a Reconstruct Total Ion Current (RTIC) and equal to a total value of the constituents with the mass numbers 0 to 100.

From FIG. 45, it can be seen that although noise is large in the sample baked at 260° C., the degassing yield is decreased as the baking temperature is increased.

### Embodiment 3

In this embodiment, organic EL properties in the cases where polyimide (PI) and polybenzoxazole (PBO) are used respectively for partition walls were examined.

Each of polyimide (PI) and polybenzoxazole (PBO) is an insulating material having good heat-resisting properties. In Embodiments 1 and 2, the TDS measurement of the single-layer samples were performed as tests for the heat-resisting properties of polyimide (PI) and polybenzoxazole (PBO) respectively, and the results were compared.

However, which heat-resisting properties are superior could not be judged only from the results of the TDS measurement.

Further, the plurality of samples of each of polyimide and polybenzoxazole were manufactured with the baking condition (the baking temperature) changed, and TDS measurement thereof were performed. Consequently, it could be confirmed that the degassing yield detected was smaller as the baking temperature of the sample was higher in either case of polyimide or polybenzoxazole.

Thus in this embodiment, in order to verify whether the above-described tendency affects initial properties or reliability of light emission of an organic EL element or not, an organic EL material was evaporated to each of substrates where PI and PBO which were baked at higher temperatures than in the standard condition were formed as partition walls, and properties thereof were evaluated.

First, a silicon oxide film was formed as a base film over a substrate at a thickness of 200 nm. After that, a first electrode was formed by using a stacked-layer film of aluminum (Al) and titanium (Ti).

A second electrode was formed using indium oxide-tin oxide (Indium Tin Oxide which is also called ITO).

Next, polyimide or polybenzoxazole which was a material of a partition wall was formed over the substrate and shaped into a desired shape. Then, development treatment was performed and baking at a temperature shown in Table 7 was performed. Note that in this embodiment, the baking temperature corresponds to the temperature of T₃ in FIG. 2.

TABLE 7

| | | Baking |
|---|---|---|
| | Partition | temperature |
| Sample | material | (° C.) |
| 1 | PI | 300 |
| 2 | | 320 |
| 3 | | 340 |
| 4 | PBO | 300 |
| 5 | | 320 |
| 6 | | 340 |

A light-emitting layer was formed using an organic material which emits green light. In this manner, organic EL elements of this embodiment were formed.

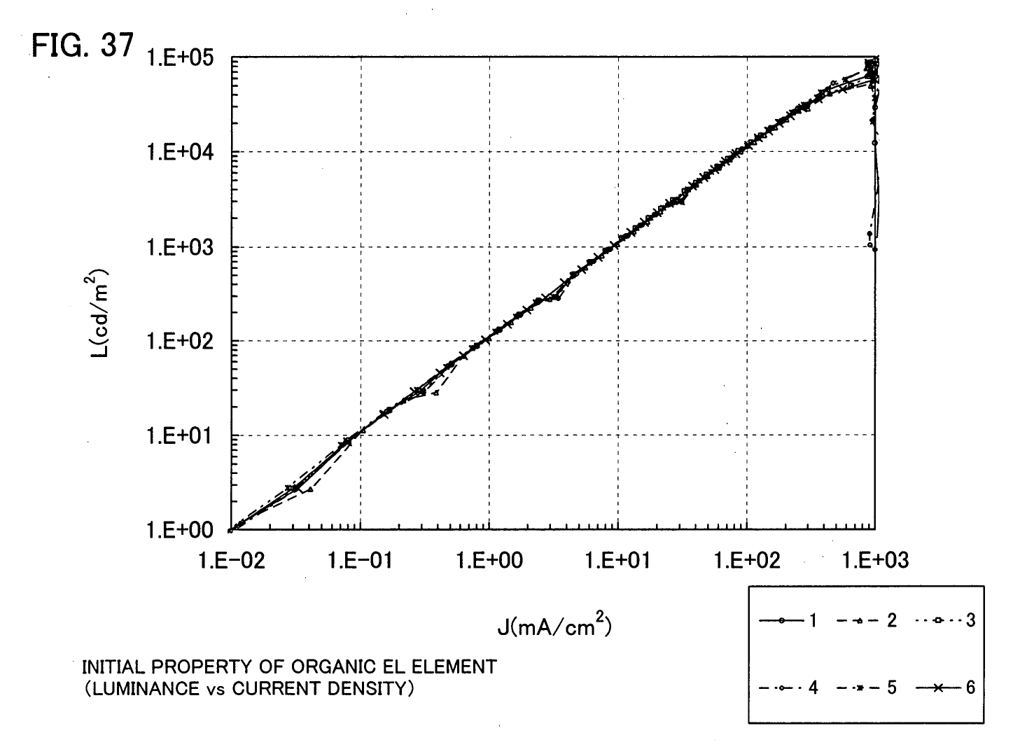

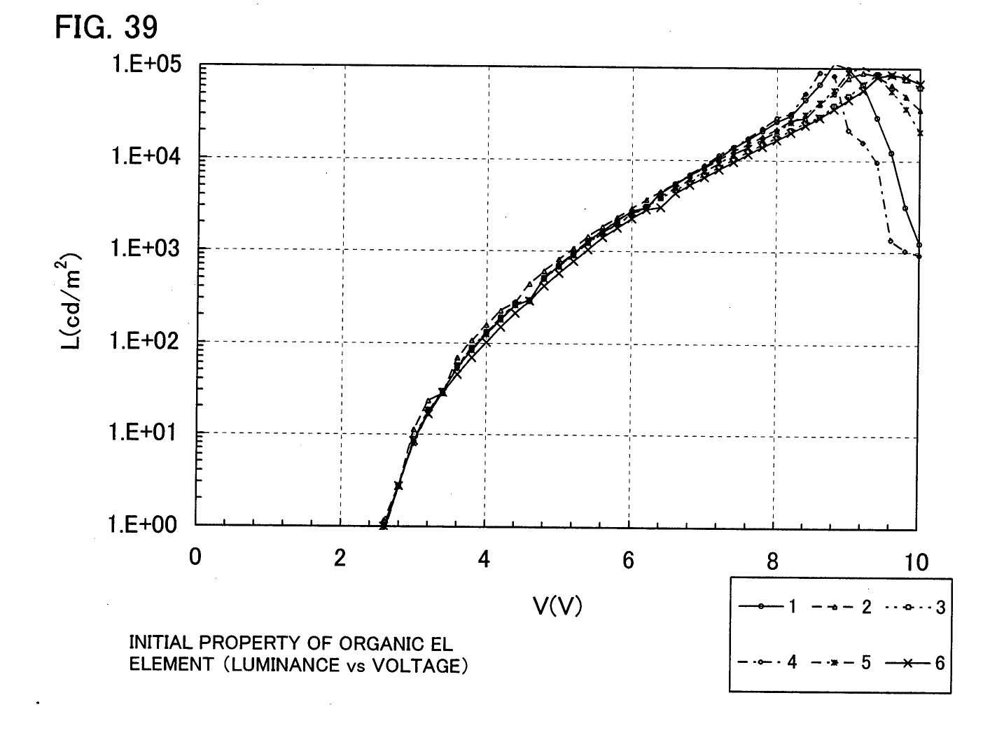

Initial properties of the manufactured organic EL elements are shown in FIGS. 37 to 40. There is little difference in properties among the elements in any diagram of them, and data was mostly overlapped in FIGS. 37, 39, and 40.

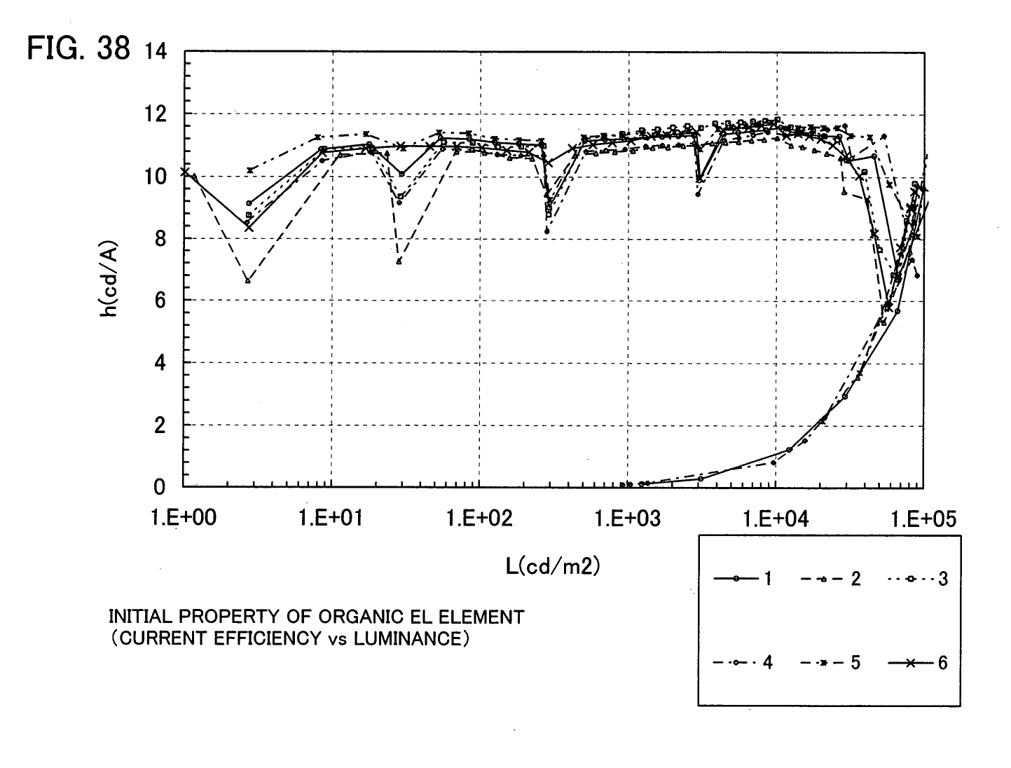

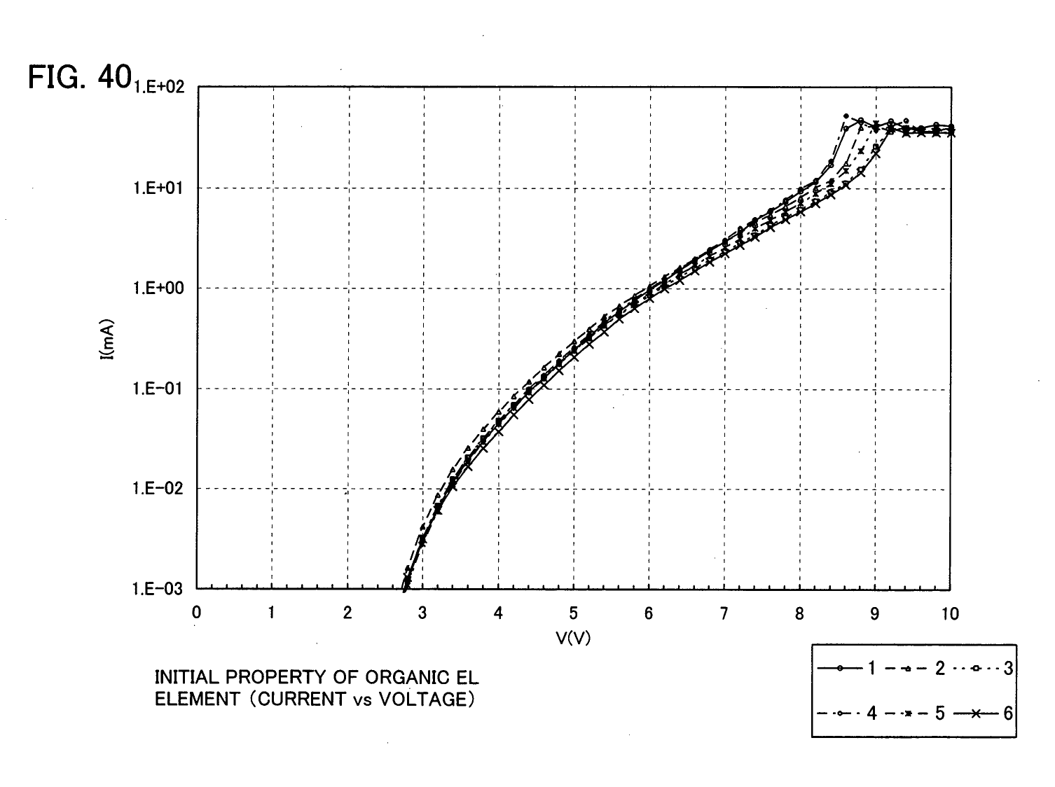

From FIG. 37, it can be seen that a current value and a luminance are directly proportional to each other in a wide range. Therefore, as is also seen from FIG. 38, the current efficiency (unit: cd/A) is a constant value in a wide range. In addition, from FIG. 40, it can be seen that current and voltage have a proportional relation to each other in a wide range where the voltage is 4 V or more.

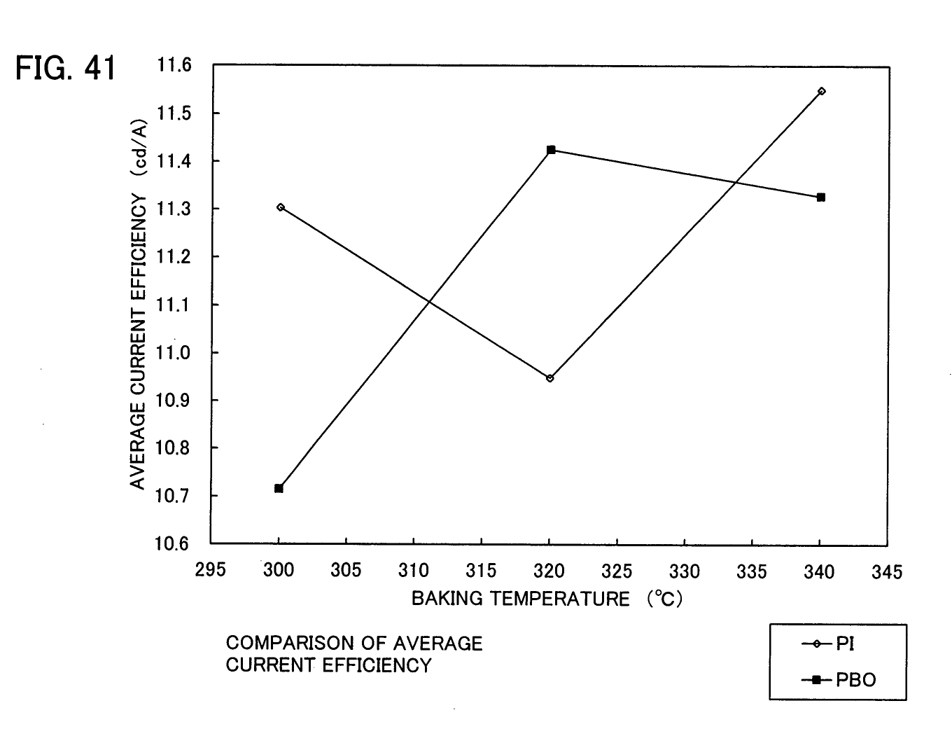

In the current efficiency in FIG. 38, there is difference among the elements, though it is not remarkable. However, from the FIG. 38, it is difficult to separately consider difference between the materials of the partition walls, difference depending on the baking condition, evaporation variation, an error, or the like. Therefore, average current efficiency in a region of 1000 cd/m² to 3000 cd/m² in FIG. 38 was plotted and compared in FIG. 41.

From FIG. 41, it can be seen that the evaporation variation, the error, or the like are large while the difference between the materials of the partition walls and the difference depending on the baking condition are not clear. There is not significant difference depending on the material between PI and PBO. Further, there is not significant difference depending on the baking temperature.

In summary of the above-described results and consideration, the material or the baking condition of the partition wall does not remarkably affect initial properties of each element.

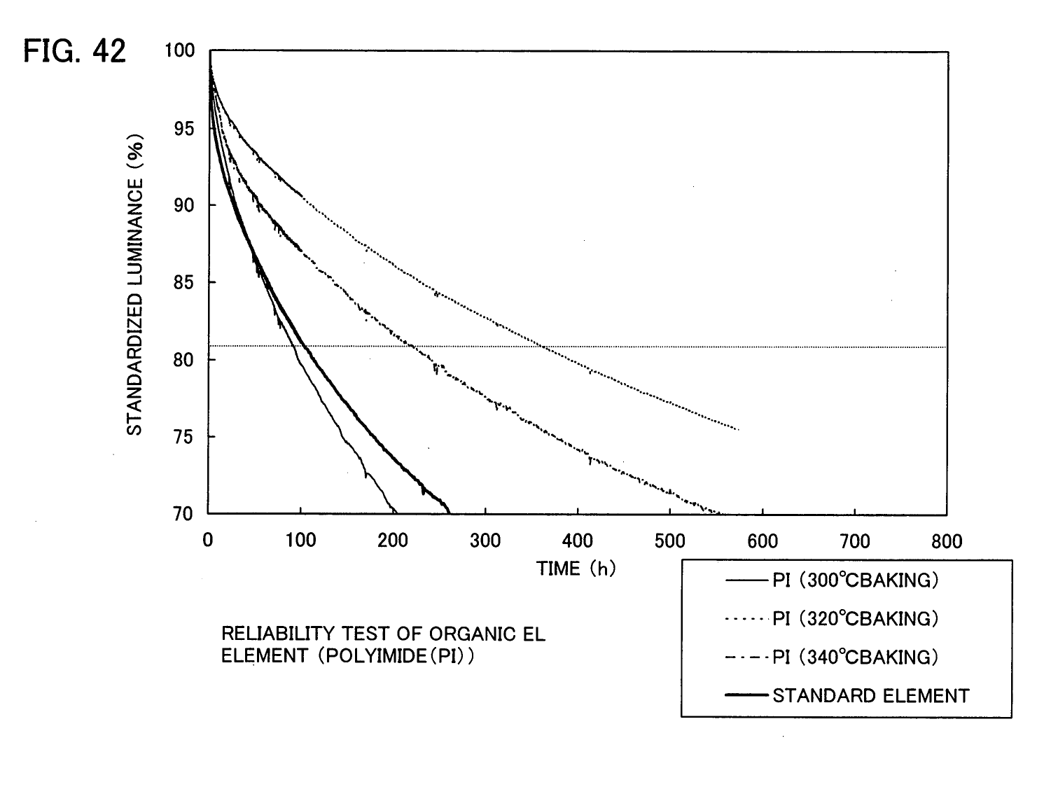

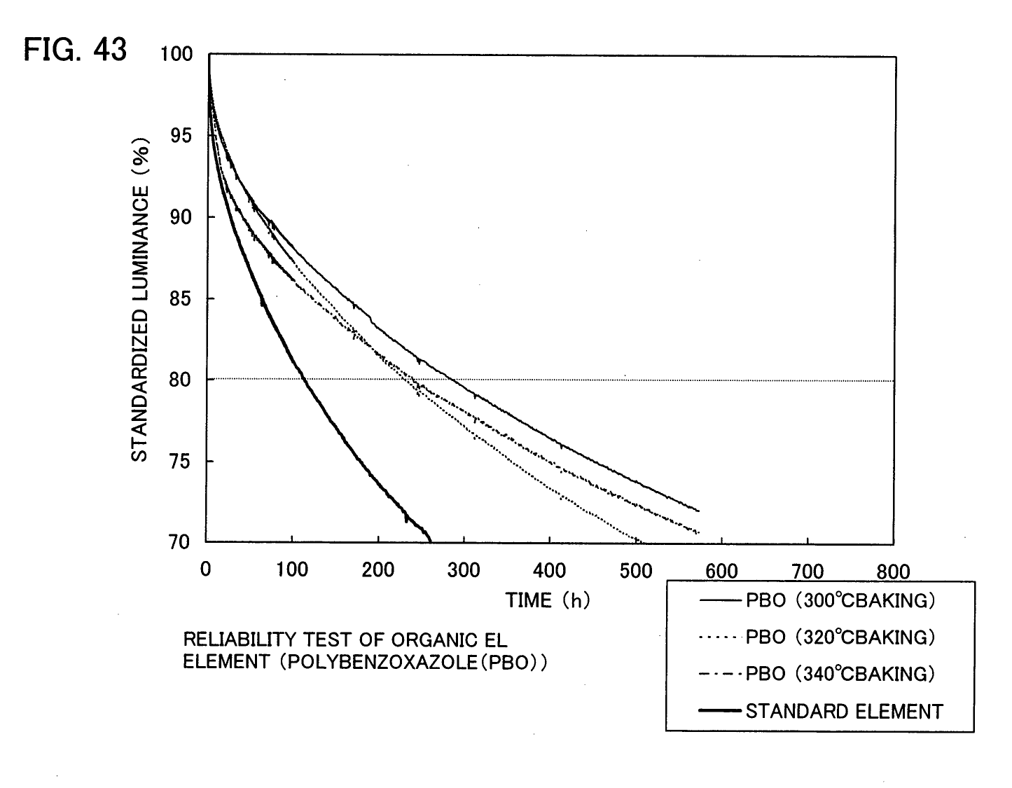

Attenuation curves of a reliability test of the organic EL elements of this embodiment are shown in FIG. 42 in the case where polyimide is used for each partition wall and in FIG. 43 in the case where polybenzoxazole is used for each partition wall.

In this embodiment, the reliability test was performed with an initial luminance of M2 each organic EL element which emits green light, of 3000 cd/m². Based on FIGS. 42 and 43, time for attenuating the luminance of each organic EL element to 80% of the initial luminance is shown in Table 8. Note that in FIGS. 42 and 43, an element with the partition material baked at 250° C. was used as a standard element.

TABLE 8

| | | Time for attenuating |
|---|---|---|
| Partition | Baking | luminance to 80% of |
| material | temperature (° C.) | initial luminance (h) |
| PI | 250 | 124 |
| | 300 | 97 |
| | 320 | 393 |
| | 340 | 240 |
| PBO | 300 | 287 |
| | 320 | 231 |
| | 340 | 241 |

As for reliability of the elements with the partition materials baked at higher temperatures which are higher than 300° C., which are evaporated to the substrates, five elements out of six elements show results greater than a result of the element baked at 250° C. Accordingly, it can be said that reliability tends to be improved as the baking temperature is increased.

As a reason why it can be considered that increase in baking temperature of the partition material contributes to increase in reliability of the EL element, decrease in degassing yield from the partition material can be considered as shown in the results of the TDS measurement.

It is known that PI is imidized at 200° C. or higher and an imidizing rate (a curing rate) thereof is 100% at 250° C. or higher. Therefore, it should be sufficient for the partition material to be baked at 250° C.

However, even in a temperature range which is equal to or higher than 250° C., it is considered that the film quality depends on the baking temperature because of the rate of content of a low-molecular-weight constituent such as a photosensitive agent, the average molecular weight, the film density, or the like, and difference in degassing yield is generated as is seen from the results of the TDS measurement.

Since the amount of gas detected by the TDS measurement is small and an actual EL element is not heated at the time of light emission, it is difficult to intuitively consider that an amount of gas by which deterioration occurs is generated from the partition material.

However, as for an EL element incorporated into a light-emitting device, since it is used continuously for hundreds or thousands of hours, it can also be considered that a certain constituent such as moisture may gradually deteriorate the EL element even if the degassing yield is very small. Therefore, as a requirement for a partition material of an EL element, it is preferable that the degassing yield be small as much as possible.

### Embodiment 4

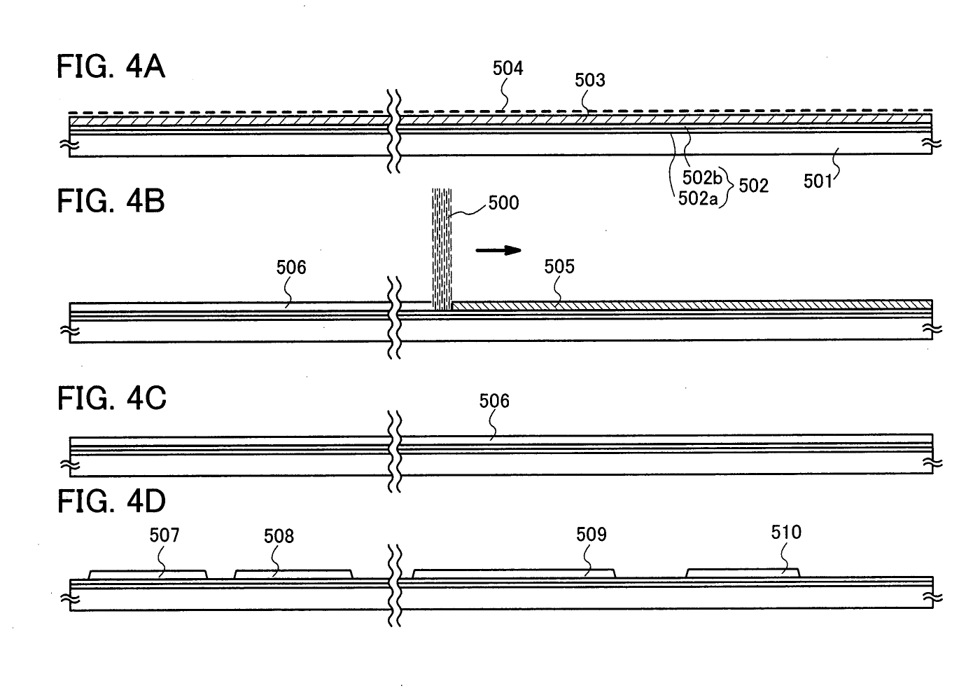

An example of using a method for manufacturing a semiconductor device using the present invention is described with reference to FIGS. 4A to 4D, 5A to 5C, 6A to 6C, 7A to 7C, 8A and 8B, 9A and 9B, 10, 11, and 12.

First, as shown in FIG. 4A, a base film 502 is formed over a substrate 501. As the substrate 501, for example, a glass substrate made of barium borosilicate glass, alumino-borosilicate glass, or the like, a quartz substrate, a stainless steel substrate, or the like can be used. Further, a substrate made of a plastic typified by PET (polyethylene terephthalate), PES (polyether sulfone), and PEN (polyethylene naphtahalate), or a flexible synthetic resin such as acrylic can also be used.

The base film 502 is provided in order to prevent an alkali metal or an alkali-earth metal such as Na contained in the substrate 501 from diffusing into a semiconductor film to adversely affect characteristics of a semiconductor element.

Silicon oxide, silicon nitride, silicon oxide containing nitrogen, silicon nitride containing oxygen, or the like can be used for the base film 502, and the base film 502 may be a single layer or have a stacked-layer structure of two layers, three layers, or the like. In addition, it is effective to provide the base film to prevent impurity diffusion in the case of using a substrate containing an alkali metal or an alkali-earth metal, such as a glass substrate, a stainless steel substrate, or a plastic substrate. However, when impurity diffusion is not matter as in the case of using a quartz substrate or the like, the base film is not necessarily provided.

In this embodiment, a silicon nitride film containing oxygen is formed as a lower-layer base film 502a at a thickness of 50 nm with SiH₄, NH₃, N₂O, N₂ and H₂ as reaction gases over the substrate, and a silicon oxide film containing nitrogen is formed as an upper-layer base film 502b at a thickness of 100 nm with SiH₄ and N₂O as reaction gases thereover. Note that, the thickness of the silicon nitride film containing oxygen may also be 140 nm and the thickness of the stacked silicon oxide film containing nitrogen may also be 100 nm.

Next, a semiconductor film 503 is formed over the base film 502. The thickness of the semiconductor film 503 is set to 25 to 100 nm (preferably 30 to 60 nm). It is to be noted that not only silicon (Si) but also silicon-germanium (SiGe) can be used as the semiconductor. In the case of using silicon germanium, the germanium concentration is preferably approximately 0.01 to 4.5 atomic %.

For the semiconductor film 503, an amorphous semiconductor that is manufactured by vapor deposition or sputtering using a semiconductor material gas such as silane or germane, a semi-amorphous semiconductor (also called a microcrystal, and hereinafter also referred to as an “SAS”), or the like can be used.

The semi-amorphous semiconductor (SAS) is a semiconductor that has an intermediate structure between amorphous and crystalline (including a single crystal and a polycrystal) structures and has a third state that is stable in terms of free energy, and includes a crystalline region that has a short-range order with lattice distortion. In at least one region of the film, a crystal region of 0.5 to 20 nm can be observed. In the case of including silicon as a main component, Raman spectrum is shifted toward a low wavenumber side which is lower than 520 cm⁻¹.

Diffraction peaks of (111) and (220), which are considered to be derived from a silicon crystal lattice, are observed in X-ray diffraction. In order to terminate dangling bonds, hydrogen or halogen is included at least at 1 atomic % or more.

The SAS is formed by glow discharge decomposition (plasma CVD) of a gas containing silicon. As the gas containing silicon, SiH₄, Si₂H₆, SiH₂Cl₂, SiHCl₃, SiCl₄, SiF₄ or the like can be used, which may be further mixed with F₂ or GeF₄. The gas containing silicon may be diluted with H₂ or with H₂ and at least one kind of rare gas elements selected from He, Ar, Kr and Ne.

The dilution ratio is in the range of 2 to 1000 times, the pressure is in the range of 0.1 to 133 Pa, and the power supply frequency is 1 to 120 MHz, preferably 13 to 60 MHz. The substrate heating temperature is preferably 300° C. or less, and the SAS can also be formed at a substrate heating temperature of 100 to 200° C.

Here, as for impurity elements taken mainly during the film formation, it is preferable that the concentration of impurities derived from atmospheric components such as oxygen, nitrogen and carbon be 1×10²⁰ cm⁻³ or less, and in particular, the oxygen concentration be 5×10¹⁹ cm⁻³ or less, more preferably 1×10¹⁹ cm⁻³ or less.

In addition, by adding a rare gas element such as helium, argon, krypton, or neon to further promote the lattice distortion, a favorable SAS with stability improved can be obtained. Alternatively, as the semiconductor film, an SAS layer which is formed by using a hydrogen-based gas may be stacked on an SAS layer which is formed by using a fluorine-based gas.

The amorphous semiconductor is typified by hydrogenated amorphous silicon or the like. Further, as described above, a semi-amorphous semiconductor or a semiconductor including a crystalline phase as a part of its semiconductor film can also be used.

In this embodiment, as the semiconductor film 503, an amorphous silicon film is formed by plasma CVD at a thickness of 54 nm.

Next, a metal element which promotes crystallization of a semiconductor is introduced into the semiconductor film 503. The method for introducing the metal element into the semiconductor film 503 is not particularly limited as long as the metal element can be existed in a surface of or inside the semiconductor film 503, and for example, sputtering, CVD, plasma treatment (including plasma CVD), an absorption method, or a method of adding a solution of a metal salt can be used.

Among them, the method of using a solution is simple and is useful in that the concentration of the metal element is easily controlled. In addition, at this time, it is preferable to form an oxide film by UV light irradiation in an oxygen atmosphere, thermal oxidation, a treatment with ozone water including a hydroxyl radical or hydrogen peroxide, or the like in order to improve surface wettability of the semiconductor film 503 and spread the solution over the entire surface of the amorphous semiconductor film.

As the metal element which promotes crystallization of a semiconductor, one or more elements selected from nickel (Ni), germanium (Ge), iron (Fe), palladium (Pd), tin (Sn), lead (Pb), cobalt (Co), platinum (Pt), copper (Cu), and gold (Au) can be used. In this embodiment, nickel (Ni) is used as the metal element, and a liquid-phase nickel acetate solution is applied as a solution 504 containing the metal element to the surface of the semiconductor film 503 by spin coating (see FIG. 4A).

Next, hydrogen in the semiconductor film 503 is released by keeping at a temperature of 450 to 500° C. for one hour in a nitrogen atmosphere. This is for reducing the threshold energy in the following crystallization by purposely forming dangling bonds in the semiconductor film 503.

Then, by performing a heat treatment at a temperature of 550 to 600° C. for 4 to 8 hours in a nitrogen atmosphere, the semiconductor film 503 is crystallized to form a crystalline semiconductor film 505. This metal element allows the crystallization temperature of the semiconductor film 503 to be a relatively low temperature of 550 to 600° C.

Next, the crystalline semiconductor film 505 is irradiated with a linear laser beam 500 to improve crystallinity furthermore (see FIG. 4B).

In the case of performing laser crystallization, a heat treatment at 500° C. for 1 hour may also be performed to the crystalline semiconductor film 505 before the laser crystallization in order to enhance resistance of the crystalline semiconductor film 505 to the laser.

For the laser crystallization, a continuous wave laser, or a pulsed oscillation laser at a repetition rate of 10 MHz or more, preferably 80 MHz or more, as a pseudo CW laser can be used.

Specifically, as continuous wave lasers, there are an Ar laser, a Kr laser, a CO₂ laser, a YAG laser, a YVO₄ laser, a YLF laser, a YAlO₃ laser, a GdVO₄ laser, a Y₂O₃ laser, a ruby laser, an alexandrite laser, a Ti:sapphire laser, a helium cadmium laser, and the like.

In addition, as pseudo CW lasers, pulsed oscillation lasers such as an Ar laser, a Kr laser, an excimer laser, a CO₂ laser, a YAG laser, a Y₂O₃ laser, a YVO₄ laser, a YLF laser, a YAlO₃ laser, a GdVO₄ laser, a glass laser, a ruby laser, an alexandrite laser, a Ti:sapphire laser, a copper vapor laser, and a gold vapor laser can be used as long as pulsed oscillation can be performed at a repetition rate of 10 MHz or more, preferably 80 MHz or more.

These pulsed oscillation lasers eventually exhibit an effect equivalent to the continuous wave laser as a result of increasing the repetition rate.

For example, in the case of using a solid laser that is capable of continuous wave oscillation, a crystal of large grain size can be obtained by irradiation with laser light of any of the second to fourth harmonics. Typically, it is preferable to use the second harmonic (532 nm) or the third harmonic (355 nm) of a YAG laser (fundamental wave: 1064 nm). For example, laser light emitted from a continuous wave YAG laser is converted into a harmonic by a non-linear optical element, and is used to irradiate the semiconductor film 505. The energy density may be set at approximately 0.01 to 100 MW/cm² (preferably 0.1 to 10 MW/cm²).

Note that the laser light irradiation may be performed in an atmosphere containing an inert gas such as a rare gas or nitrogen. This makes it possible to suppress roughness of the semiconductor surface due to laser light irradiation and suppress variations in threshold voltage caused by variations in interface state density.

A crystalline semiconductor film 506 with crystallinity more improved is formed by irradiating the semiconductor film 505 with the laser beam 500 described above (see FIG. 4C).

Next, as shown in FIG. 4D, island-shaped semiconductor films 507 to 510 are formed by using the crystalline semiconductor film 506. These island-shaped semiconductor films 507 to 510 serve as active layers of TFTs formed in the subsequent process.

Next, an impurity for controlling the threshold value is introduced into the island-shaped semiconductor films 507 to 510. In this embodiment, boron (B) is introduced into the island-shaped semiconductor films 507 to 510 by doping with diborane (B₂H₆).

Next, an insulating film 511 is formed so as to cover the island-shaped semiconductor films 507 to 510. For the insulating film 511, for example, silicon oxide, silicon nitride, silicon oxide containing nitrogen, or the like can be used. In addition, plasma CVD, sputtering, or the like can be used as a film formation method thereof.

Next, after forming a conductive film over the insulating film 511, a first conductive film 512 and a second conductive film 513 are formed, and by using them, gate electrodes 515 to 519 are formed.

The gate electrodes 515 to 519 are formed by using a single layer of a conductive film or a stacked-layer structure of two or more layers of conductive films. In the case where two or more conductive films are stacked, the gate electrodes 515 to 519 may be formed by stacking an element selected from tantalum (Ta), tungsten (W), titanium (Ti), molybdenum (Mo), and aluminum (Al), an alloy material containing the element as a main component, or a compound material. Alternatively, each gate electrode may be formed by using a semiconductor film typified by a polycrystalline silicon film doped with an impurity element such as phosphorous (P).

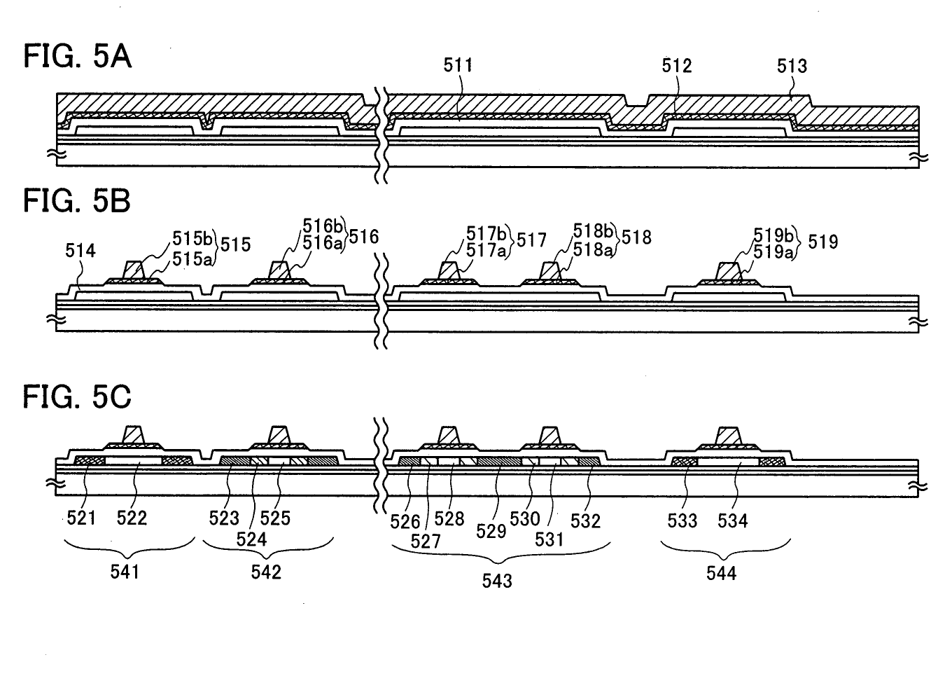

In this embodiment, as the first conductive film 512, for example, a tantalum nitride (TaN) film is formed at a thickness of 10 to 50 nm, e.g., at 30 nm, first. Then, as the second conductive film 513, for example, a tungsten (W) film is formed over the first conductive film 512 at a thickness of 200 to 400 nm, e.g., at 370 nm, thereby forming a stacked-layer film of the first conductive film 512 and the second conductive film 513 (see FIG. 5A).

Next, by performing anisotropic etching continuously to the second conductive film and the first conductive film and then by performing isotropic etching to the second conductive film, upper-layer gate electrodes 515b to 519b and lower-layer gate electrodes 515a to 519a are formed. In this manner, the gate electrodes 515 to 519 are formed (see FIG. 5B).

Each of the gate electrodes 515 to 519 may be formed as a part of a gate wiring, or a gate wiring may be separately formed to be connected to the gate electrodes 515 to 519.

In addition, a part of the insulating film 511 is also etched at the time of forming the gate electrodes 515 to 519, to form a gate insulating film 514.

Then, by using each of the gate electrodes 515 to 519 or a resist as a mask, each of the island-shaped semiconductor films 507 to 510 is doped with an impurity which imparts one conductivity (n-type or p-type conductivity) to form source regions, drain regions, and further low-concentration impurity regions, and the like.

First, phosphorous (P) is introduced into the island-shaped semiconductor films by using phosphine (PH₃) at an accelerating voltage of 60 to 120 keV and at a dosage of 1×10¹³ to 1×10¹⁵ cm⁻². By this introduction of the impurity, a channel formation region 525 for an n-channel TFT 542, and channel formation regions 528 and 531 for an n-channel TFT 543 are formed.

In addition, in order to manufacture p-channel TFTs 541 and 544, boron (B) is introduced into the island-shaped semiconductor films by using diborane (B₂H₆) at an applied voltage is 60 to 100 keV, e.g., 80 keV, and at a dosage is 1×10¹³ to 5×10¹⁵ cm⁻², e.g., 3×10¹⁵ cm⁻². Consequently, source or drain regions 521 and 533 for p-channel TFTs 541 and 544 respectively are formed, and channel formation regions 522 and 534 for the p-channel TFTs 541 and 544 respectively are formed by this introduction of the impurity.

Further, phosphorous (P) is introduced into the island-shaped semiconductor films 508 and 509 for the n-channel TFTs 542 and 543 by using phosphine (PH₃) at an applied voltage of 40 to 80 keV, e.g., at 50 keV, and at a dosage of 1.0×10¹⁵ to 2.5×10¹⁶ cm⁻², e.g., at 3.0×10¹⁵ cm⁻². Consequently, a low-concentration impurity region 524 and a source or drain region 523 for the n-channel TFT 542, and low-concentration impurity regions 527 and 530 and source or drain regions 526, 529, and 532 for the n-channel TFT 543 are formed (see FIG. 5C).

In this embodiment, phosphorous (P) is contained at a concentration of 1×10¹⁹ to 5×10²¹ cm⁻³ in each of the source or drain region 523 for the n-channel TFT 542, and the source or drain regions 526, 529, and 532 for the n-channel TFT 543.

In addition, phosphorous (P) is contained at a concentration of 1×10¹⁸ to 5×10¹⁹ cm⁻³ in each of the low-concentration impurity region 524 for the n-channel TFT 542, and the low-concentration impurity regions 527 and 530 for the n-channel TFT 543.

Further, boron (B) is contained at a concentration of 1×10¹⁹ to 5×10²¹ cm⁻³ in each of the source or drain region 521 for the p-channel TFT 541, and the source or drain region 533 for the p-channel TFT 544.

Next, a first interlayer insulating film 551 is formed so as to cover the island-shaped semiconductor films 507 to 510, the gate insulating film 514, and the gate electrodes 515 to 519.

As the first interlayer insulating film 551, an insulating film containing silicon, e.g., a silicon oxide film, a silicon nitride film, a silicon oxide film containing nitrogen, or a stacked-layer film thereof is formed by plasma CVD or sputtering. It is needless to say that the first interlayer insulating film 551 is not limited to the silicon oxide film containing nitrogen, the silicon nitride film, or the stacked-layer film thereof, and another insulating film containing silicon may also be used as a single layer or in a stacked-layer structure.

In this embodiment, after introducing the impurities, a silicon oxide film containing nitrogen is formed by plasma CVD at a thickness of 50 nm, and the impurities are activated by a laser irradiation method or heating at 550° C. in a nitrogen atmosphere for 4 hours after the silicon oxide film containing nitrogen is formed.

Next, a silicon nitride film is formed by plasma CVD at a thickness of 50 nm, and a silicon oxide film containing nitrogen is further formed at a thickness of 600 nm. This stacked-layer film of the silicon oxide film containing nitrogen, the silicon nitride film, and the silicon oxide film containing nitrogen is the first interlayer insulating film 551.

Next, hydrogenation is performed by heating the whole at 410° C. for 1 hour to release hydrogen from the silicon nitride film.

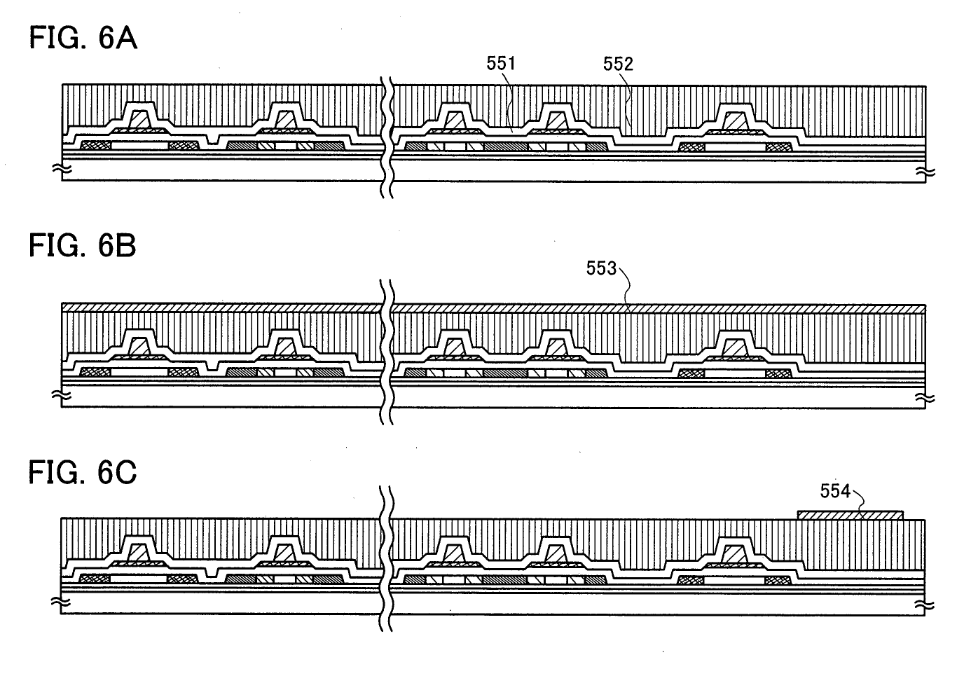

Next, a second interlayer insulating film 552 which functions as a planarization film is formed so as to cover the first interlayer insulating film 551 (see FIG. 6A).

For the second interlayer insulating film 552, a photosensitive or non-photosensitive organic material (polyimide, acrylic, polyamide, polyimideamide, resist, or benzocyclobutene), siloxane, or a stacked-layer structure thereof can be used. As the organic material, a positive photosensitive organic resin or a negative photosensitive organic resin can be used.

Siloxane has a skeleton structure formed by bonding silicon (Si) and (O), where an organic group containing at least hydrogen (e.g., an alkyl group or aromatic hydrocarbon) is used as a substituent. A fluoro group may also be used as a substituent. Alternatively, an organic group containing at least hydrogen and a fluoro group may be used as substituents.

In this embodiment, siloxane is formed by spin coating for the second interlayer insulating film 552.

Further, a third interlayer insulating film may be formed over the second interlayer insulating film 552. As the third interlayer insulating film, a film through which moisture, oxygen, or the like is hardly transmitted as compared with other insulating films is used. Typically, a silicon nitride film, a silicon oxide film, a silicon nitride film containing oxygen (composition ratio: N>O), or a silicon oxide film containing nitrogen (composition ratio: N<O) that is obtained by sputtering or CVD, a thin film containing carbon as a main component (e.g., a diamond-like carbon film (a DLC film) or a carbon nitride film (a CN film)), or the like can be used.

Next, a transparent conductive film 553 is formed over the second interlayer insulating film 552 (see FIG. 6B). For the transparent conductive film used in the present invention, an indium tin oxide containing silicon (Si) (also called an indium tin oxide containing Si) is used.

As well as the indium tin oxide containing Si, a transparent conductive film such as a conductive film formed by using a target in which zinc oxide (ZnO), tin oxide (SnO₂), indium oxide, or indium oxide is mixed with zinc oxide (ZnO) at 2 to 20 wt % may also be used. In this embodiment, for the transparent conductive film 553, an indium tin oxide containing Si is stacked by sputtering at a thickness of 110 nm.

Next, a pixel electrode 554 is formed of the transparent conductive film 553 (see FIG. 6C). For forming the pixel electrode 554, the transparent conductive film 553 is preferably etched by wet etching.

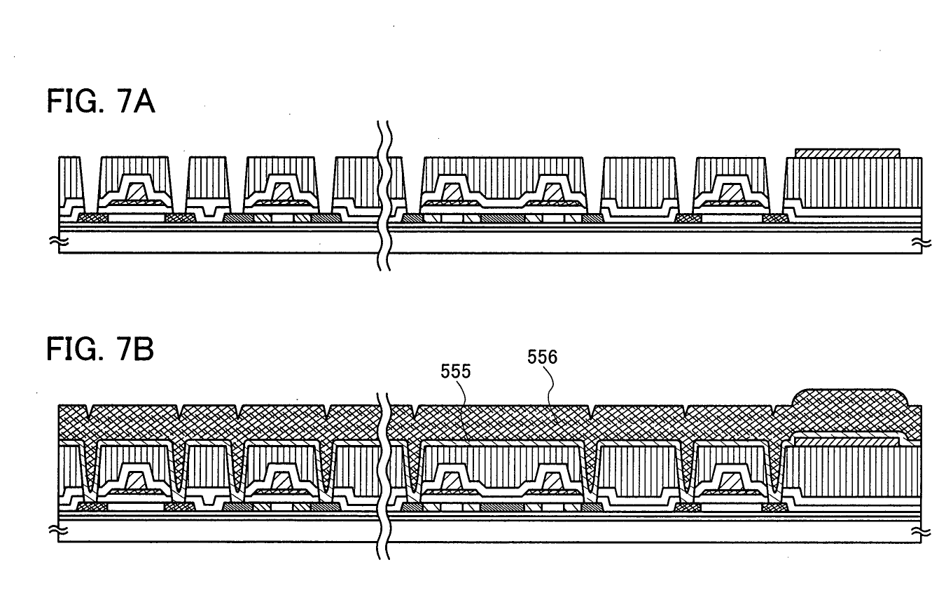

The first interlayer insulating film 551 and the second interlayer insulating film 552 are etched to form contact holes reaching to the island-shaped semiconductor films 507 to 510 in the first interlayer insulating film 551 and the second interlayer insulating film 552 (see FIG. 7A).

A third conductive film 555 and a fourth conductive film 556 are formed over the second interlayer insulating film 552 through the contact holes (see FIG. 7B).

For this embodiment, a film made of molybdenum (Mo), tungsten (W), tantalum (Ta), or chromium (Cr), or an alloy film using any element thereof is preferably used as the third conductive film 555. In this embodiment, molybdenum (Mo) is stacked by sputtering at a thickness of 100 nm.

In addition, a film containing aluminum as a main component is formed by sputtering as the fourth conductive film 556. As the film containing aluminum as a main component, an aluminum film, an aluminum alloy film containing at least one kind of element of nickel, cobalt, and iron, or an aluminum alloy film containing carbon and at least one kind of element of nickel, cobalt, and iron can be used. In this embodiment, an aluminum film is formed by sputtering at a thickness of 700 nm.

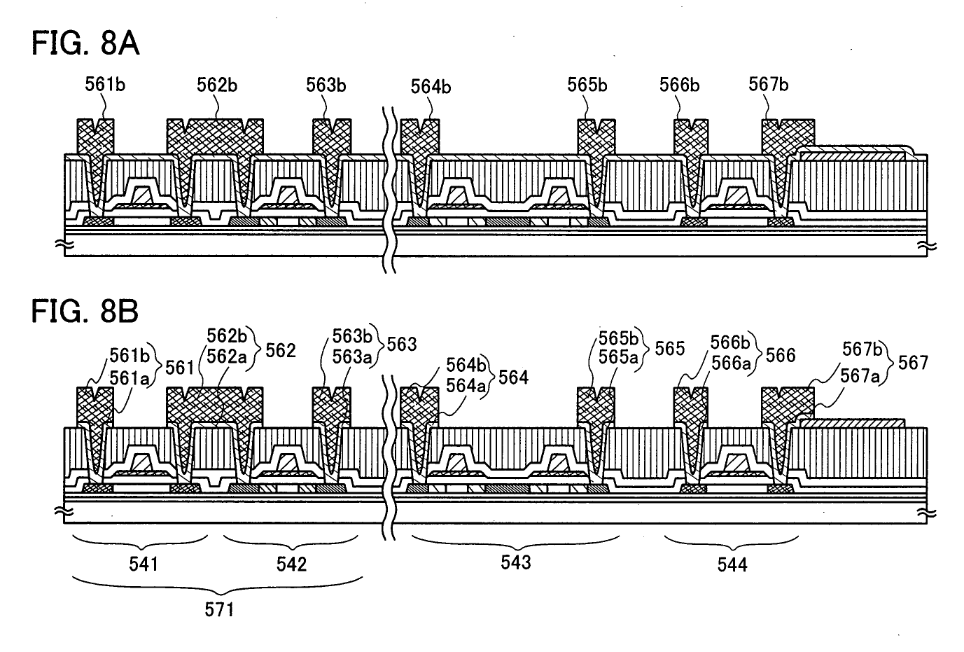

Next, the fourth conductive film 556 is etched to form electrodes 561b, 562b, 563b, 564b, 565b, 566b, and 567b (see FIG. 8A).

For etching of the fourth conductive film 556, dry etching is performed by using a mixed gas of BCl₃ and Cl₂. In this embodiment, dry etching is performed by supplying BCl₃ and Cl₂ at flow rates of 60 sccm and 20 sccm respectively.

At this time, the third conductive film 555 functions as an etching stopper, so that the pixel electrode 554 is not in contact with the mixed gas of BCl₃ and Cl₂. Therefore, particles can be prevented from being generated.

Next, the third conductive film 555 is etched to form electrodes 561a, 562a, 563a, 564a, 565a, 566a, and 567a. In this embodiment, dry etching of the third conductive film 555 is performed by supplying CF₄ and O₂ at flow rates of 30 to 60 sccm and 40 to 70 sccm respectively.

At this time, since the pixel electrode 554 does not react with CF₄ or O₂, fine particles are not formed. In addition, the pixel electrode 554 functions as an etching stopper for etching the third conductive film 555 to form the electrode 567a.

In this manner, electrodes 561 to 567 are formed. For each of the electrodes 561 to 567, an electrode and a wiring may be formed of the same material in the same process, or an electrode and a wiring may be formed separately and connected to each other.

Through the series of steps described above, the n-channel TFTs 542 and 543 and the p-channel TFTs 541 and 544 are formed. The n-channel TFT 542 and the p-channel TFT 541 are connected by the electrode 562 to form a CMOS circuit 571 (see FIG. 8B).

In this manner, a TFT substrate of a dual-emission type display device is formed. In FIG. 8B, a driver circuit portion 595 and a pixel portion 596 are provided over the substrate 501, and the CMOS circuit 571 including the n-channel TFT 542 and the p-channel TFT 541 is formed in the driver circuit portion 595.

In the pixel portion 596, the p-channel TFT 544 which functions as a pixel TFT and the n-channel TFT 543 which drives the pixel TFT are formed. In this embodiment, the pixel electrode 554 functions as an anode of a light-emitting element.

After forming the electrodes 561 to 567, an insulator 581 (called a partition wall, a barrier, or the like) covering an end portion of the pixel electrode 554 is formed. For the insulator 581, polyimide or polybenzoxazole is used.

A baking method of the insulator 581 may be the same as that described in the embodiment mode. A solvent can be removed by heating at a temperature which is lower than the curing temperature, e.g., at 150 to 200° C. Then, baking at a temperature which is higher than the curing temperature, e.g., at 300 to 350° C. is performed, thereby an insulator (a partition wall) with less degassing yield can be obtained.

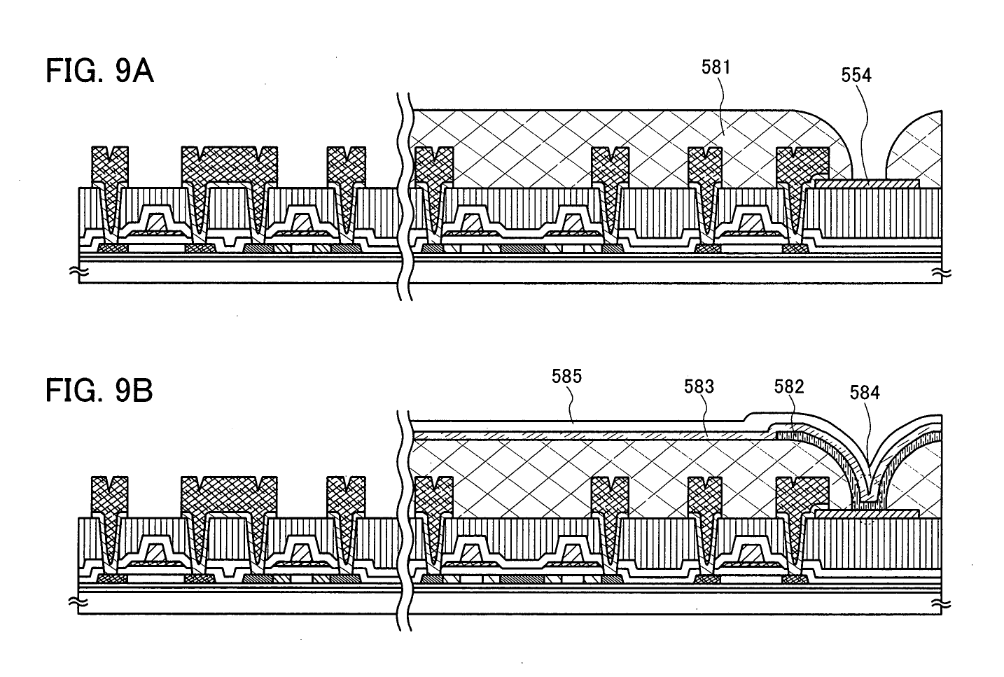

After forming the insulator 581, an organic compound layer 582 is formed. Then, a second electrode 583, i.e., a cathode of the light-emitting element is formed at a thickness of 10 to 800 nm (see FIG. 9B). For the second electrode 583, as well as an indium oxide (ITO), for example, a target in which an indium tin oxide containing a Si element is mixed with zinc oxide (ZnO) at 2 to 20 wt % can be used.

The organic compound layer 582 includes a hole injecting layer 601, a hole transporting layer 602, a light-emitting layer 603, an electron transporting layer 604, and an electron injecting layer 605 which are formed by an evaporation method or a coating method. Note that, in order to improve reliability of the light-emitting element, it is preferable to perform vacuum heating for degassing before the organic compound layer 582 is formed. For example, before evaporation of an organic compound material is performed, it is preferable to perform a heat treatment at 200 to 300° C. in a reduced-pressure atmosphere or an inert atmosphere in order to remove gas contained in the substrate.

Next, molybdenum oxide (MoOx), 4,4′-bis[N-(1-naphthyl)-N-phenyl-amino]-biphenyl (α-NPD), and rubrene are co-evaporated selectively over the pixel electrode 554 by using an evaporation mask to form the hole injecting layer 601.

Further, as well as MoOx, a material having high hole-injecting properties such as copper phthalocyanine (CuPc), vanadium oxide (VOx), ruthenium oxide (RuOx), and tungsten oxide (WOx) can be used. Further alternatively, a polymer material having high hole injecting properties such as a polyethylene dioxythiophene solution (PEDOT) or a polystyrene sulphonate solution (PSS) may be stacked by a coating method, for the hole injecting layer 601.

Then, α-NPD is selectively evaporated by using an evaporation mask to form the hole transporting layer 602 over the hole injecting layer 601. Note that as well as α-NPD, a material having high hole transporting properties typified by an aromatic amine compound such as 4,4′-bis[N-(3-methylphenyl)-N-phenyl-amino]-biphenyl (abbreviation: TPD), 4,4′,4″-tris(N,N-diphenyl-amino)-triphenylamine (abbreviation: TDATA), and 4,4′,4″-tris[N-(3-methylphenyl)-N-phenyl-amino]-triphenylamine (abbreviation: MTDATA) can be used.

Next, the light-emitting layer 603 is selectively formed. For forming a full-color display device, an evaporation mask is aligned for each light emission color (each of R, G, and B) and evaporation is performed selectively.

Then, Alq₃ (tris(8-quinolinolato)aluminum) is selectively evaporated by using an evaporation mask to form the electron transporting layer 604 over the light-emitting layer 603. Note that as well as Alq₃, a material having high electron transporting properties typified by a metal complex having a quinoline skeleton or a benzoquinoline skeleton, such as tris(4-methyl-8-quinolinolato)aluminum (abbreviation: Almq₃), bis(10-hydroxybenzo[h]-quinolinato)beryllium (abbreviation: BeBq₂), and bis(2-methyl-8-quinolinolato)-4-phenylphenolato-aluminum (abbreviation: BAlq), and the like can be used.

Further alternatively, a metal complex having an oxazole-based or thiazole-based ligand, such as bis[2-(2-hydroxyphenyl)-benzoxazolato]zinc (abbreviation: Zn(BOX)₂) and bis[2-(2-hydroxyphenyl)-benzothiazolato]zinc (abbreviation: Zn(BTZ)₂), or the like can be used.

Further alternatively, as well as the metal complex, the following can also be used for the electron transporting layer 604 because the electron transporting properties are high: 2-(4-biphenylyl)-5-(4-tert-butylphenyl)-1,3,4-oxadiazole (abbreviation: PBD); 1,3-bis[5-(p-tert-butylphenyl)-1,3,4-oxadiazole-2-yl]benzene (abbreviation: OXD-7); 3-(4-tert-butylphenyl)-4-phenyl-5-(4-biphenylyl)-1,2,4-triazole (abbreviation: TAZ); 3-(4-tert-butylphenyl)-4-(4-ethylphenyl)-5-(4-biphenylyl)-1,2,4-triazole (abbreviation: p-EtTAZ); bathophenanthroline (abbreviation: BPhen); bathocuproine (abbreviation: BCP); and the like.

Then, 4,4-bis(5-methylbenzoxazole-2-yl)stilbene (abbreviation: BzOs) and lithium (Li) are co-evaporated to form the electron injecting layer 605 over the entire surface covering the electron transporting layer 604 and insulator 581. Damage due to sputtering at the time of forming the second electrode 583 which is performed in a subsequent process is suppressed by using benzoxazole derivative (BzOs).

Further, as well as BzOs:Li, a material having high electron injecting properties such as a compound of an alkali metal or an alkali-earth metal, e.g., CaF₂, lithium fluoride (LiF), cesium fluoride (CsF), or the like, can be used. Further alternatively, a mixture of Alq₃ and magnesium (Mg) can be used.

Next, the second electrode 583, i.e., the cathode of the organic light-emitting element is formed over the electron injecting layer 605 at a thickness of 10 to 800 nm. For the second electrode 583, as well as an indium tin oxide (ITO), for example, an indium tin oxide containing Si or a conductive film formed using a target in which indium oxide is mixed with zinc oxide (ZnO) at 2 to 20 wt % can be used.

Note that although a light-transmitting electrode is used as the second electrode 583 because the case of manufacturing the dual-emission type display device is described in this embodiment, a reflective conductive material may be used to form the second electrode 583 in the case of manufacturing a one-side emission type display device. It is preferable to use a metal, an alloy, an electrically conducting compound, a mixture thereof, or the like which is low in work function (a work function of 3.8 eV or less) as such a conductive material.

Note also that specific examples of the material for the second electrode 583 include elements that belong to Group 1 or 2 of the periodic table of the elements, i.e., alkali metals such as Li and Cs and alkali-earth metals such as Mg, Ca, and Sr, and alloys (Mg:Ag and Al:Li) and compounds (LiF, CsF, and CaF₂) containing any of these elements, and transition metals containing rare-earth metals. Further, the second electrode 583 can also be formed of a stacked-layer structure of the above-described material and a metal (including an alloy) such as Al or Ag.

In this manner, a light-emitting element 584 is manufactured. Respective materials for the anode 554, the organic compound layer 582, and the cathode 583 forming the light-emitting element 584 are appropriately selected, and each film thickness is also adjusted. It is preferable that the same material be used for the anode and the cathode and the anode and the cathode have the similar thicknesses, more preferably be as thin as 100 nm.

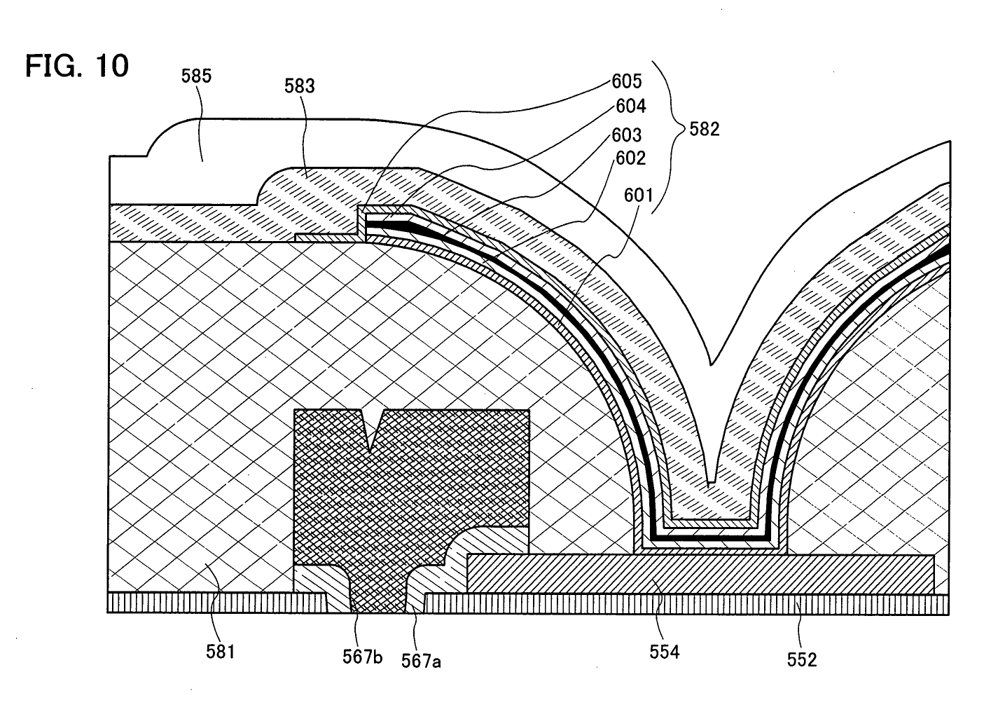

Further, if necessary, a transparent protective layer 585 which prevents moisture penetration is formed so as to cover the light-emitting element 584 as shown in FIG. 9B. As the transparent protective layer 585, a silicon nitride film, a silicon oxide film, a silicon nitride film containing oxygen (composition ratio: N>O), or a silicon oxide film containing nitrogen (composition ratio: N<O) that is obtained by sputtering or CVD, a thin film containing carbon as a main component (e.g., a diamond-like carbon film (a DLC film) or a carbon nitride film (a CN film)), or the like can be used. Note that FIG. 10 is a diagram magnifying a part of FIG. 9B.

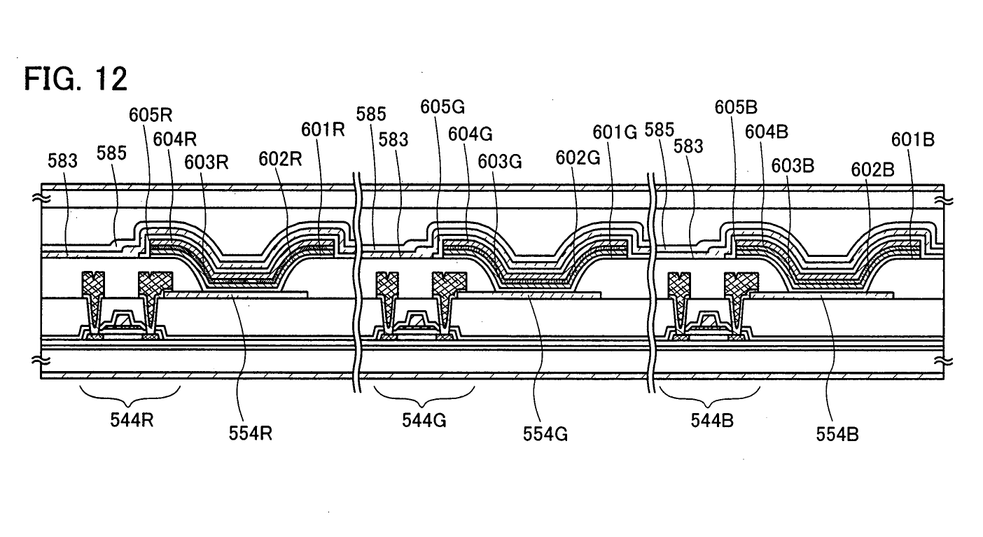

FIG. 12 shows an example where pixel TFTs in a pixel portion are formed separately for each of RGB. In a pixel for red (R), a pixel TFT 544R is connected to a pixel electrode 554R, and a hole injecting layer 601R, a hole transporting layer 602R, a light-emitting layer 603R, an electron transporting layer 604R, an electron injecting layer 605R, the cathode 583, and the transparent protective film 585 are formed.

In a pixel for green (G), a pixel TFT 544G is connected to a pixel electrode 554G and a hole injecting layer 601G, a hole transporting layer 602G, a light-emitting layer 603G, an electron transporting layer 604G, an electron injecting layer 605G; the cathode 583, and the transparent protective film 585 are formed.

In a pixel for blue (B), a pixel TFT 544B is connected to a pixel electrode 554B, and a hole injecting layer 601B, a hole transporting layer 602B, a light-emitting layer 603B, an electron transporting layer 604B, an electron injecting layer 605B, the cathode 583, and the transparent protective film 585 are formed.

For the light-emitting layer 603R which emits red light, a material such as Alq₃:DCM or Alq₃:rubrene:BisDCJTM is used. For the light-emitting layer 603G which emits green light, a material such as Alq₃:DMQD (N,N′-dimethylquinacridone) or Alq₃:coumarin 6 is used. For the light-emitting layer 603B which emits blue light, a material such as α-NPD or tBu-DNA is used.

Next, a sealing material 593 containing a gap material for ensuring substrate spacing is provided over the driver circuit portion 595 including the CMOS circuit 571, and a second substrate 591 is attached to the substrate 501. Also as the second substrate 591, a light-transmitting glass substrate or quartz substrate may be used.

It is to be noted that a drying agent may be disposed as an air gap (an inert gas) in a region 592 of the space between the substrates 501 and 591, below which the pixel portion 596 is provided, or the region 592 may be filled with a transparent sealing material (e.g., an ultraviolet-curing or thermosetting epoxy resin).

Since the pixel electrode 554 and the second electrode 583 of the light-emitting element are formed of light-transmitting materials, light can be extracted from two directions, that is, from both sides of one light-emitting element.

With the panel structure described above, light emission from the top surface can be made substantially equal to light emission from the bottom surface.

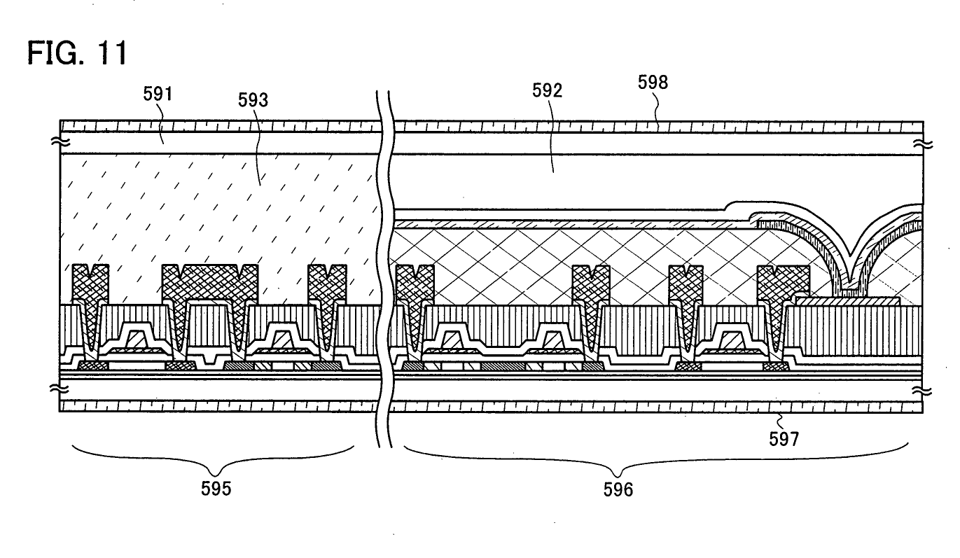

Further, optical films (polarizing plates or circularly polarizing plates) 597 and 598 are preferably provided for the substrates 501 and 591 respectively to improve the contrast (see FIG. 11).

Note that although the TFTs are top-gate TFTs in this embodiment, the structures thereof are not limited to the structures; a bottom-gate (inversely staggered) TFT or a staggered TFT can also be used as appropriate. In addition, the TFTs are not limited to single-gate TFTs; a multi-gate TFT that has a plurality of channel formation regions, for example, a double-gate TFT may also be employed.

In the light-emitting device in accordance with this embodiment, generation of moisture, gas, or the like from the insulator 581 can be suppressed, thereby a favorable display device with high reliability and long life can be manufactured.

This embodiment can be combined freely with any description of the embodiment mode and Embodiments 1 to 3, if necessary.

### Embodiment 5

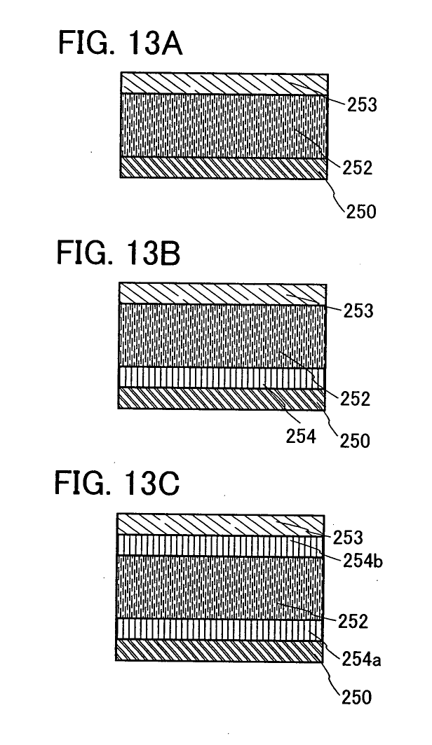

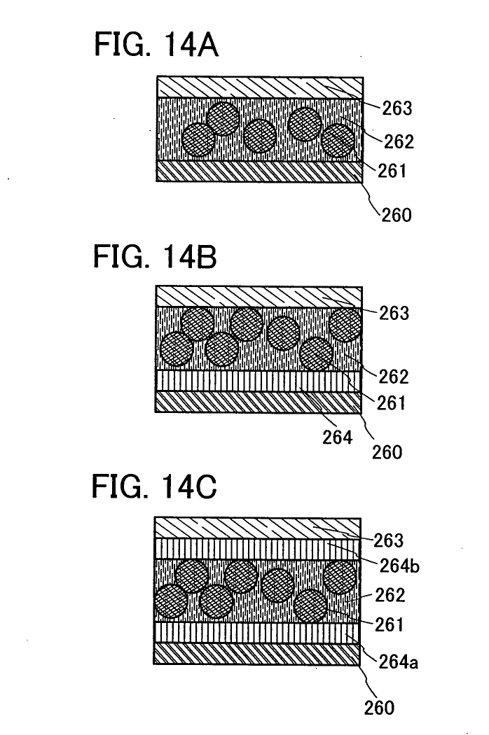

In this embodiment, examples of applying the present invention to an inorganic EL element are described with reference to FIGS. 13A to 13C and 14A to 14C.

A light-emitting element utilizing electroluminescence is distinguished by whether a light-emitting material is an organic compound or an inorganic compound; in usual, the former is called an organic EL element and the latter is called an inorganic EL element. Described in Embodiment 4 is the example of using an organic EL element in the present invention.

An inorganic EL element is classified into a dispersion type inorganic EL element and a thin-film type inorganic EL element, depending on its element structure. The former and the latter are different in that the former has an electroluminescence layer where particles of the light-emitting material are dispersed in a binder whereas the latter has an electroluminescence layer formed of a thin film of the light-emitting material. However, the former and the latter have in common that electrons accelerated by a high electric field are necessary.

Note that, as a mechanism of light emission that is obtained, there are donor-acceptor recombination type light emission that utilizes a donor level and an acceptor level, and localized type light emission that utilizes inner-shell electron transition of a metal ion. In usual, in many cases, a dispersion type inorganic EL element exhibits donor-acceptor recombination type light emission, and a thin-film type inorganic EL element exhibits localized type light emission.

The light-emitting material which can be used in the present invention includes a host material and an impurity element to be a light-emission center. By changing the impurity element that is contained, light emission of various colors can be obtained. As a manufacturing method of the light-emitting material, various methods such as a solid phase method and a liquid phase method (a coprecipitation method) can be used. Further, an evaporative decomposition method, a double decomposition method, a method by heat decomposition reaction of a precursor, a reversed micelle method, a method in which such a method is combined with high temperature baking, a liquid phase method such as a lyophilization method, or the like can also be used.

The solid phase method is a method in which a host material, and an impurity element or a compound containing an impurity element are weighed, mixed in a mortar, heated and baked in an electric furnace to be reacted, thereby containing the impurity element in the host material. The baking temperature is preferably 700 to 1500° C. This is because the solid reaction does not progress when the temperature is too low, whereas the host material is decomposed when the temperature is too high. Note that although baking may be performed in a powder state, it is preferable to perform baking in a pellet state. Although baking is necessarily performed at a comparatively high temperature, the solid phase method is easy; thus, the solid phase method is suitable for mass production because of high productivity.

The liquid phase method (a coprecipitation method) is a method in which a host material or a compound containing a host material is reacted with an impurity element or a compound containing an impurity element in a solution, dried, and then baked. Particles of the light-emitting material are distributed uniformly, and the reaction can progress even when the grain size is small and the baking temperature is low.

As the host material used for the light-emitting material, sulfide, oxide, or nitride can be used. As sulfide, for example, zinc sulfide (ZnS), cadmium sulfide (CdS), calcium sulfide (CaS), yttrium sulfide (Y₂S₃), gallium sulfide (Ga₂S₃), strontium sulfide (SrS), barium sulfide (BaS), or the like can be used. As oxide, for example, zinc oxide (ZnO), yttrium oxide (Y₂O₃), or the like can be used. As nitride, for example, aluminum nitride (AlN), gallium nitride (GaN), indium nitride (InN), or the like can be used.

Further, as the host material used for the light-emitting material, zinc selenide (ZnSe), zinc telluride (ZnTe), or the like can also be used, or alternatively a ternary mixed crystal such as calcium sulfide-gallium (CaGa₂S₄), strontium sulfide-gallium (SrGa₂S₄), or barium sulfide-gallium (BaGa₂S₄) may also be used.

As the light-emission center of localized type light emission, manganese (Mn), copper (Cu), samarium (Sm), terbium (Tb), erbium (Er), thulium (Tm), europium (Eu), cerium (Ce), praseodymium (Pr), or the like can be used. Note that a halogen element such as fluorine (F) or chlorine (Cl) may be added as charge compensation.

On the other hand, as the light-emission center of donor-acceptor recombination type light emission, a light-emitting material containing a first impurity element which forms a donor level and a second impurity element which forms an acceptor level can be used. As the first impurity element, for example, fluorine (F), chlorine (Cl), aluminum (Al), or the like can be used. As the second impurity element, for example, copper (Cu), silver (Ag), or the like can be used.

In the case of synthesizing the light-emitting material of donor-acceptor recombination type light emission by the solid phase method, the host material, the first impurity element or a compound containing the first impurity element, and the second impurity element or a compound containing the second impurity element are each measured, mixed in a mortar, heated and baked in an electric furnace.

As the host material, any of the above described host materials can be used. As the first impurity element or the compound containing the first impurity element, for example, fluorine (F), chlorine (Cl), aluminum sulfate (Al₂S₃), or the like can be used. As the second impurity element or the compound containing the second impurity element, for example, copper (Cu), silver (Ag), copper sulfide (Cu₂S), silver sulfide (Ag₂S), or the like can be used.

The baking temperature is preferably 700 to 1500° C. This is because the solid reaction does not progress when the temperature is too low, whereas the host material is decomposed when the temperature is too high. Note that although baking may be performed in a powder state, it is preferable to perform baking in a pellet state.

As the impurity element in the case of utilizing solid reaction, a compound containing the first impurity element and the second impurity element may be combined. In this case, since the impurity element is easily diffused and solid reaction progresses easily, a uniform light-emitting material can be obtained. Further, since an unnecessary impurity element does not enter, a light-emitting material having high purity can be obtained. As the compound containing the first impurity element and the second impurity element, for example, copper chloride (CuCl), silver chloride (AgCl), or the like can be used.

Note that the concentration of these impurity elements may be 0.01 to 10 atomic % with respect to the host material, and is preferably in the range of 0.05 to 5 atomic %.

In the case of a thin-film type inorganic EL element, a light-emitting layer is a layer containing the above light-emitting material, which can be formed by a vacuum evaporation method such as a resistance heating evaporation method or an electron beam evaporation (EB evaporation) method, a physical vapor deposition method (PVD) such as sputtering, a chemical vapor deposition method (CVD) such as an organic metal CVD method or a hydride transport low-pressure CVD method, an atomic layer epitaxy method (ALE), or the like.

FIGS. 13A to 13C show examples of thin-film type inorganic EL elements which can be used as light-emitting elements. In FIGS. 13A to 13C, each light-emitting element includes a first electrode layer 250, an electroluminescent layer 252, and a second electrode layer 253.

For manufacturing light-emitting devices using the light-emitting elements of FIGS. 13A to 13C respectively, the light-emitting element 584 in FIG. 11 may be replaced with each light-emitting element of FIGS. 13A to 13C in the light-emitting device shown in FIG. 11 described in Embodiment 4.

Each of the light-emitting elements shown in FIGS. 13B and 13C has a structure in which an insulating layer is provided between the electrode layer and the electroluminescent layer in the light-emitting element of FIG. 13A. The light-emitting element shown in FIG. 13B includes an insulating layer 254 between the first electrode layer 250 and the electroluminescent layer 252, and the light-emitting element shown in FIG. 13C includes an insulating layer 254a between the first electrode layer 250 and the electroluminescent layer 252 and an insulating layer 254b between the second electrode layer 253 and the electroluminescent layer 252. Thus the insulating layer may be provided only between one of the pair of electrode layers interposing the electroluminescent layer and the electroluminescent layer, or both between one of the pair of electrode layers and the electroluminescent layer and between the other of the pair of electrode layers and the electroluminescent layer. Further, the insulating layer may be either a single layer or a stacked-layer including a plurality of layers.

Further, although the insulating layer 254 is provided so as to be in contact with the first electrode layer 250 in FIG. 13B, the order of the insulating layer and the electroluminescent layer may be reversed such that the insulating layer 254 is provided so as to be in contact with the second electrode layer 253.

In the case of a dispersion type inorganic EL element, particles of a light-emitting material are dispersed in a binder to form an electroluminescent layer film. In the case where particles each having a desired size cannot be sufficiently obtained depending on a manufacturing method of the light-emitting material, processing into particles may be performed by crushing with a mortar or the like. A binder is a substance for fixing the particles of the light-emitting material in the dispersed state, and holding with a form as an electroluminescent layer. The light-emitting material is uniformly dispersed and fixed in the electroluminescent layer by the binder.

In the case of a dispersion type inorganic EL element, the electroluminescent layer can be formed by a droplet discharge method by which an electroluminescent layer can be selectively formed, a printing method (e.g., screen printing or offset printing), a coating method such as spin coating, a dipping method, a dispenser method, or the like. The thickness thereof is not particularly limited; however, it is preferably in a range of 10 to 1000 nm. In addition, in the electroluminescent layer containing the light-emitting material and the binder, the ratio of the light-emitting material is preferably more than or equal to 50 wt % and less than or equal to 80 wt %.

FIGS. 14A to 14C show examples of dispersion type inorganic EL elements which can be used as light-emitting elements. In FIG. 14A, a light-emitting element has a stacked-layer structure of a first electrode layer 260, an electroluminescent layer 262, and a second electrode layer 263, and includes a light-emitting material 261 held by a binder in the electroluminescent layer 262.

For manufacturing light-emitting devices using the light-emitting elements of FIGS. 14A to 14C respectively, the light-emitting element 584 in FIG. 11 may be replaced with each light-emitting element of FIGS. 14A to 14C in the light-emitting device shown in FIG. 11 described in Embodiment 4.

As the binder which can be used in this embodiment, an organic material or an inorganic material can be used, or a mixed material of an organic material and an inorganic material may also be used. As the organic material, a resin such as a polymer having a comparatively high dielectric constant like a cyanoethyl cellulose-based resin, polyethylene, polypropylene, a polystyrene-based resin, a silicone resin, an epoxy resin, or vinylidene fluoride can be used. Further, a heat-resistant high molecule such as aromatic polyamide or polybenzimidazole, or a siloxane resin may also be used.

A siloxane resin corresponds to a resin containing a Si—O—Si bond. Siloxane is composed of a skeleton structure formed by the bond of silicon (Si) and oxygen (O). As a substituent thereof, an organic group containing at least hydrogen (e.g., an alkyl group or aromatic hydrocarbon) is used. Further, a fluoro group may also be used as a substituent. Further, an organic group containing at least hydrogen and a fluoro group may also be used as substituents.

Further, a vinyl resin such as polyvinyl alcohol or polyvinyl butyral, or a resin material such as a phenol resin, a novolac resin, an acrylic resin, a melamine resin, a urethane resin, or an oxazole resin (polybenzoxazole) may also be used. A dielectric constant can also be controlled by mixing the above-described resin with microparticles having a high dielectric constant such as barium titanate (BaTiO₃) or strontium titanate (SrTiO₃) as appropriate.

As the inorganic material contained in the binder, a material selected from the following can be used: silicon oxide (SiOₓ), silicon nitride (SiNₓ), silicon containing oxygen and nitrogen, aluminum nitride (AlN), aluminum containing oxygen and nitrogen or aluminum oxide (Al₂O₃), titanium oxide (TiO₂), BaTiO₃, SrTiO₃, lead titanate (PbTiO₃), potassium niobate (KNbO₃), lead niobate (PbNbO₃), tantalum oxide (Ta₂O₅), barium tantalate (BaTa₂O₆), lithium tantalate (LiTaO₃), yttrium oxide (Y₂O₃), zirconium oxide (ZrO₂), zinc sulfide (ZnS), and other substances containing an inorganic material. By mixing the organic material with an inorganic material having a high dielectric constant (by adding or the like), a dielectric constant of the electroluminescent layer containing the light-emitting material and the binder can be further controlled and increased.

In a manufacturing process, the light-emitting material is dispersed in a solution containing a bindel However, as a solvent of the solution containing the binder which can be used in this embodiment, it is preferable to select such a solvent that dissolves a binder material and can make a solution with the viscosity which is suitable for a method for forming the electroluminescent layer (various wet processes) and a desired film thickness. An organic solvent or the like can be used and, for example, in the case where a siloxane resin is used as the binder, propylene glycolmonomethyl ether, propylene glycolmonomethyl ether acetate (also called PGMEA), 3-methoxy-3-methyl-1-butanol (also called MMB), or the like can be used.

Each of the light-emitting elements shown in FIGS. 14B and 14C has a structure in which an insulating layer is provided between the electrode layer and the electroluminescent layer in the light-emitting element of FIG. 14A. The light-emitting element shown in FIG. 14B includes an insulating layer 264 between the first electrode layer 260 and the electroluminescent layer 262, and the light-emitting element shown in FIG. 14C includes an insulating layer 264a between the first electrode layer 260 and the electroluminescent layer 262 and an insulating layer 264b between the second electrode layer 263 and the electroluminescent layer 262. Thus the insulating layer may be provided only between one of the pair of electrode layers interposing the electroluminescent layer and the electroluminescent layer, or both between one of the pair of electrode layers and the electroluminescent layer and between the other of the pair of electrode layers and the electroluminescent layer. Further, the insulating layer may be either a single layer or a stacked-layer including a plurality of layers.

Further, although the insulating layer 264 is provided so as to be in contact with the first electrode layer 260 in FIG. 14B, the order of the insulating layer and the electroluminescent layer may be reversed such that the insulating layer 264 is provided so as to be in contact with the second electrode layer 263.

Although the insulating layers 254 and 254a and 254b in FIGS. 13B and 13C, and the insulating layers 264 and 264a and, 264b in FIGS. 14B and 14C are not particularly limited, such an insulating layer is preferably high in withstand voltage and is dense in film quality, and more preferably high in dielectric constant.

For example, silicon oxide (SiO₂), yttrium oxide (Y₂O₃), titanium oxide (TiO₂), aluminum oxide (Al₂O₃), hafnium oxide (HfO₂), tantalum oxide (Ta₂O₅), barium titanate (BaTiO₃), strontium titanate (SrTiO₃), lead titanate (PbTiO₃), silicon nitride (Si₃N₄), zirconium oxide (ZrO₂), or the like, or a mixed film or a staked-layer film of two or more kinds thereof can be used.

Such an insulating film can be formed by sputtering, evaporation, CVD, or the like. Further, the insulating layer may also be formed by dispersing particles of such an insulating material in a binder. The binder material may be formed of the same material and by the same method as the binder contained in the electroluminescent layer. A film thickness of the insulating layer is not particularly limited, and is preferably in the range of 10 to 1000 nm.

Each light-emitting element described in this embodiment, which can emit light when a voltage is applied between the pair of the electrode layers interposing the electroluminescent layer, can be operated either by DC drive or AC drive.

By applying the present invention to an inorganic EL element, generation of gas or moisture from a partition wall (an insulator) can be suppressed. In particular, by preventing moisture which adversely affects an inorganic EL element from being generated, lives of an inorganic EL element and a light-emitting device using the inorganic EL element can be made longer than usual ones.

This embodiment can be combined freely with any description of the embodiment mode and the other embodiments, if necessary.

### Embodiment 6

Electronic equipment to which the present invention is applied includes a camera such as a video camera or a digital camera, a goggle-type display, a navigation system, a sound reproduction device (e.g., a car audio system), a computer, a game machine, a portable information terminal (e.g., a mobile computer, a cellular phone, a portable game machine, or an electronic book), an image reproduction device provided with a recording medium (specifically, a device provided with a display that can reproduce a recording medium such as a Digital Versatile Disc (DVD) and display the image), and the like.

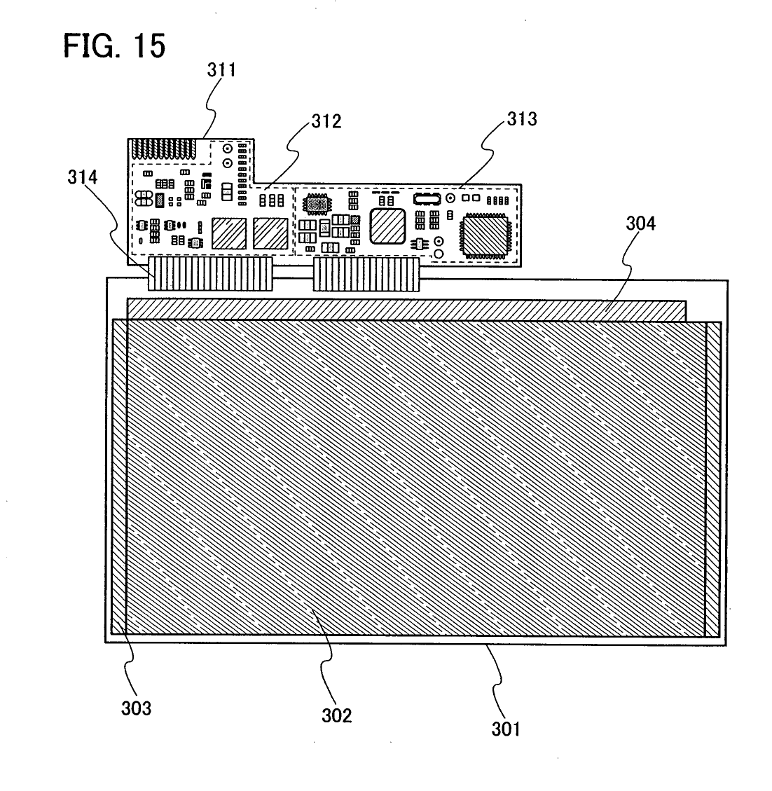

Specific examples of the electronic equipment are shown in FIGS. 15, 16, 17A and 17B, 18, 19, 20, and 21A to 21E.

FIG. 15 shows an EL module in which a display panel 301 and a circuit board 311 are combined. The circuit board 311 includes a control circuit 312, a signal dividing circuit 313, and the like, and is electrically connected to the display panel 301 by a connection wiring 314.

This display panel 301 includes a pixel portion 302 including a plurality of pixels, a scan line driver circuit 303, and a signal line driver circuit 304 which supplies a video signal to a selected pixel. The display panel 301 of the EL module may be manufactured by using the method for manufacturing the display device, which is described in Embodiment 4 or 5.

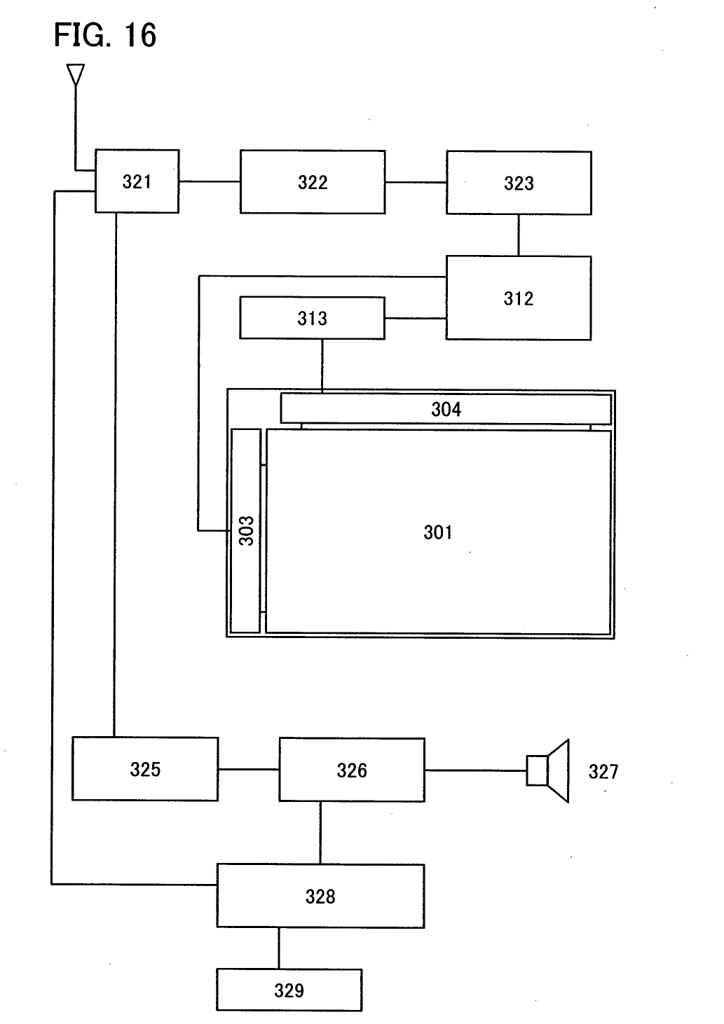

A television receiver can be completed by the EL module shown in FIG. 15. FIG. 16 is a block diagram showing a main structure of the receptor. A tuner 321 receives an image signal and an audio signal. The image signal is processed by an image signal amplifier circuit 322, an image signal processing circuit 323 which converts a signal outputted from the image signal amplifier circuit 322 into a color signal corresponding to each color of red, green, and blue, and a control circuit 312 for converting the image signal into an input specification of a driver IC. The control circuit 312 outputs signals to both of a scan line side and a signal line side. In the case of digital driving, the signal dividing circuit 313 may be provided on the signal line side to divide an input digital signal into m signals to be supplied.

The audio signal of the signals received by the tuner 321 is transmitted to an audio signal amplifier circuit 325, and output thereof is supplied to a speaker 327 through an audio signal processing circuit 326. A control circuit 328 receives control information of a receiving station (a received frequency) and volume from an input portion 329, and transmits signals to the tuner 321 and the audio signal processing circuit 326.

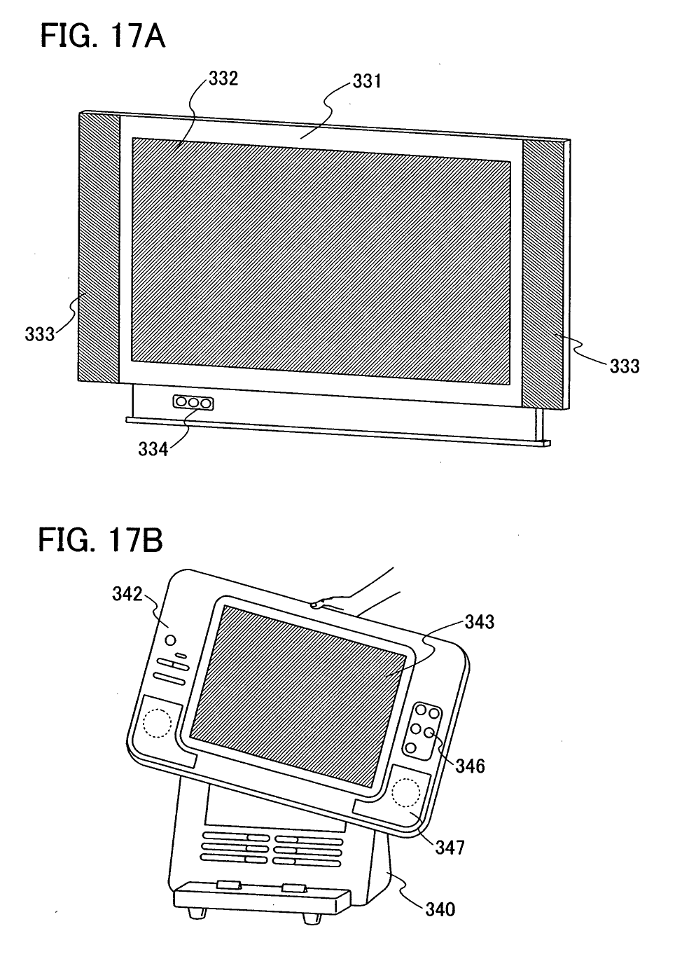

As shown in FIG. 17A, a television receiver can be completed by incorporating the EL module into a housing 331. The EL module forms a display screen 332. In addition, a speaker 333, operation switches 334, or the like are provided as appropriate.

FIG. 17B shows a television receiver of which only a display can be taken along wirelessly. A battery and a signal receptor are incorporated in a housing 342, and a display portion 343 and a speaker portion 347 are driven by the battery. The battery can be charged repeatedly by a charger 340. Further, the charger 340 can transmit and receive image signals, and transmit the image signals to the signal receptor of the display. The housing 342 is controlled with an operation key 346.

In addition, the device shown in FIG. 17B can also be called an image audio two-way communication device because signals can be transmitted also from the housing 342 to the charger 340 by operating the operation key 346. It can also be called a usual-purpose remote-control device because communication control of another electronic equipment is also possible by transmitting signals from the housing 342 to the charger 340 by operating the operation key 346 and further making another electronic equipment receive signals which can be transmitted from the charger 340. The present invention can be applied to the display portion 343.

By using the present invention for each television receiver shown in FIGS. 15, 16, 17A and 17B, a favorable television receiver with high reliability can be obtained.

It is needless to say that the present invention can be applied not only to the television receiver but also to various uses such as a monitor of a personal computer, an information display panel at a train station, an airport, or the like, and an advertising display panel on a street, particularly as a large-area display medium.

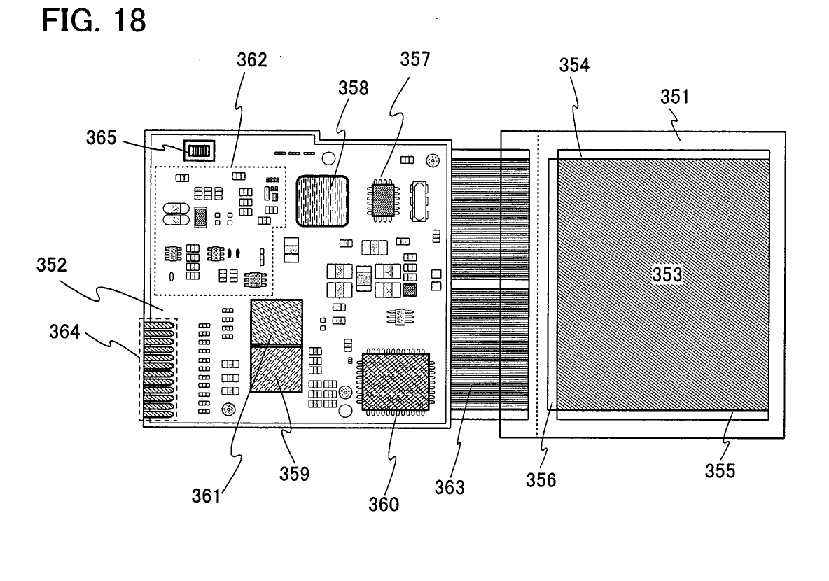

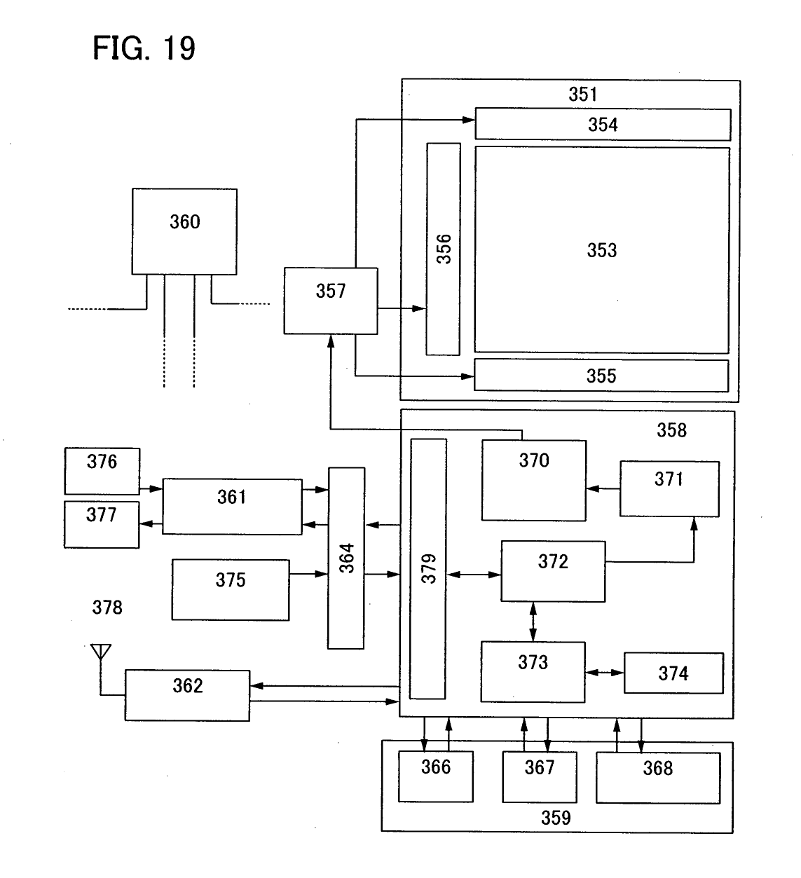

FIGS. 18 and 19 show a module in which a display panel 351 is combined with a printed wiring board 352. The display panel 351 includes a pixel portion 353 including a plurality of pixels, a first scan line driver circuit 354, a second scan line driver circuit 355, and a signal line driver circuit 356 which supplies a video signal to a selected pixel.

The printed wiring board 352 includes a controller 357, a central processing unit (CPU) 358, a memory 359, a power supply circuit 360, an audio processing circuit 361, a transmitting-receiving circuit 362, and the like. The printed wiring board 352 and the display panel 351 are connected by a flexible printed circuit (FPC) 363. The printed wiring board 352 may also be provided with a capacitor, a buffer circuit, or the like so that noise on a power supply voltage or a signal or delay in signal rising is prevented. Further, the controller 357, the audio processing circuit 361, the memory 359, the CPU 358, the power supply circuit 360, or the like can be mounted on the display panel 351 by using a COG (Chip On Glass) method. The COG method allows the size of the printed wiring board 352 to be reduced.

Various control signals are inputted and outputted through an interface 364 provided for the printed wiring board 352. In addition, an antenna port 365 for transmitting and receiving signals to and from an antenna is provided for the printed wiring board 352.

FIG. 19 is a block diagram of the module shown in FIG. 18. This module includes a VRAM 366, a DRAM 367, a flash memory 368, and the like as the memory 359. Data of an image to be displayed on the panel, image data or audio data, and various programs are stored in the VRAM 366, the DRAM 367, and the flash memory respectively.

The power supply circuit 360 supplies power for operating the display panel 351, the controller 357, the CPU 358, the audio processing circuit 361, the memory 359, and the transmitting-receiving circuit 362. In addition, depending on the panel specifications, the power supply circuit 360 may be provided with a current source.

The CPU 358 includes a control signal generating circuit 370, a decoder 371, a register 372, an operational circuit 373, a RAM 374, an interface 379 for the CPU 358, and the like. Various signals inputted to the CPU 358 through the interface 379 are once held in the register 372, and then inputted into the operational circuit 373, the decoder 371, or the like. In the operational circuit 373, operation is performed based on the inputted signals, and locations to which various instructions are transmitted are specified. On the other hand, the signal inputted into the decoder 371 is decoded and inputted into the control signal generating circuit 370. Based on the inputted signal, the control signal generating circuit 370 generates signals including various instructions, and transmits to the locations specified by the operational circuit 373, specifically, the memory 359, the transmitting-receiving circuit 362, the audio processing circuit 361, the controller 357, or the like.

Each of the memory 359, the transmitting-receiving circuit 362, the audio processing circuit 361, and the controller 357 operates in accordance with the received instruction. The operations are briefly described below.

A signal inputted from an input means 375 is transmitted through the interface 364 to the CPU 358 mounted on the printed wiring board 352. The control signal generating circuit 370 coverts image data stored in the VRAM 366 into a predetermined format in accordance with the signal transmitted from the input means 375 such as a pointing device or a keyboard, and transmits to the controller 357.

The controller 357 performs data processing to the signal including the image data transmitted from the CPU 358 in accordance with the panel specifications, and supplies to the display panel 351. In addition, based on a power supply voltage inputted from the power supply circuit 360 and various signals inputted from the CPU 358, the controller 357 generates a Hsync signal, a Vsync signal, a clock signal CLK, an alternating voltage (AC Cont), and a switching signal L/R, and supplies to the display panel 351.

In the transmitting-receiving circuit 362, signals that are as radio waves transmitted and received at an antenna 378 are processed, and specifically, high-frequency circuits such as an isolator, a band pass filter, a VCO (Voltage Controlled Oscillator), an LPF (Low Pass Filter), a coupler, and a balun are included. In the transmitting-receiving circuit 362, a signal including audio information among signals that are transmitted and received is transmitted to the audio processing circuit 361 in accordance with an instruction from the CPU 358.

The signal including the audio information, which has been transmitted in accordance with the instruction of the CPU 358, is demodulated into an audio signal in the audio processing circuit 361, and transmitted to a speaker 377. In addition, an audio signal transmitted from a microphone 376 is modulated in the audio processing circuit 361, and transmitted to the transmitting-receiving circuit 362 in accordance with an instruction from the CPU 358.

The controller 357, the CPU 358, the power supply circuit 360, the audio processing circuit 361, and the memory 359 can be mounted as a package of this embodiment. This embodiment can be applied to any circuit other than high-frequency circuits such as an isolator, a band pass filter, a VCO (Voltage Controlled Oscillator), an LPF (Low. Pass Filter), a coupler, and a balun.

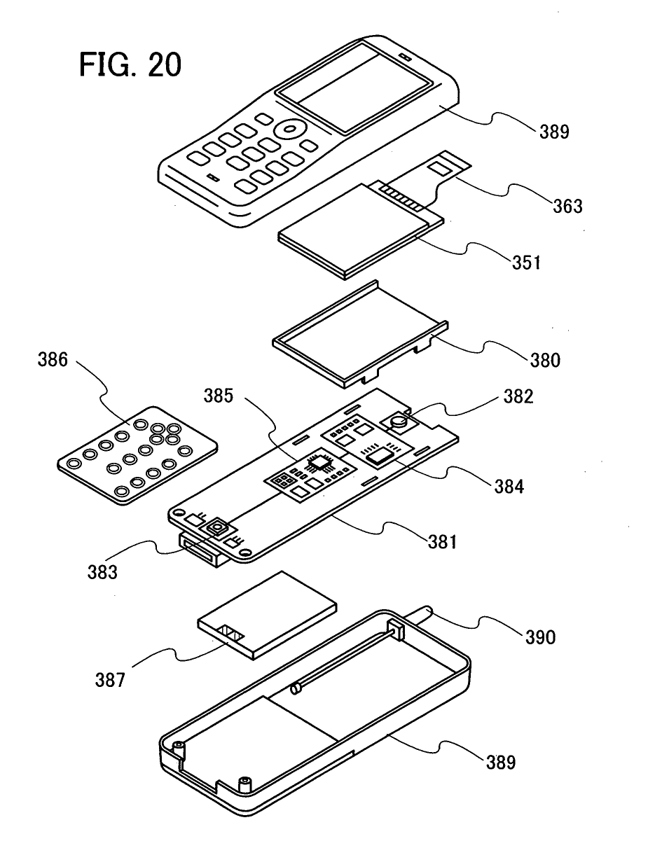

FIG. 20 shows one mode of a cellular phone including the module shown in FIGS. 18 and 19. The display panel 351 is incorporated in a housing 380 so as to be removable. The shape and size of the housing 380 can be changed as appropriate depending on the size of the display panel 351. The housing 380 fixing the display panel 351 is attached to a printed board 381 to be assembled as a module.

The display panel 351 is connected to the printed board 381 via the FPC 363. Over the printed board 381, a speaker 382, a microphone 383, a transmitting-receiving circuit 384, and a signal processing circuit 385 including a CPU, a controller, and the like are formed. This module is combined with an input means 386, a battery 387, and an antenna 390, and is put in a housing 389. The pixel portion of the display panel 351 is arranged so as to be seen from a window formed in the housing 389.

The cellular phone in accordance with this embodiment can be changed in various modes depending on the function or use thereof. For example, even when the cellular phone is provided with a plurality of panels or the housing is divided into a plurality of parts as appropriate and can be opened and closed with a hinge, the advantageous effect described above can be obtained.

By using the present invention for the cellular phone shown in FIGS. 18, 19, and 20, a favorable cellular phone with long life and high reliability can be obtained.

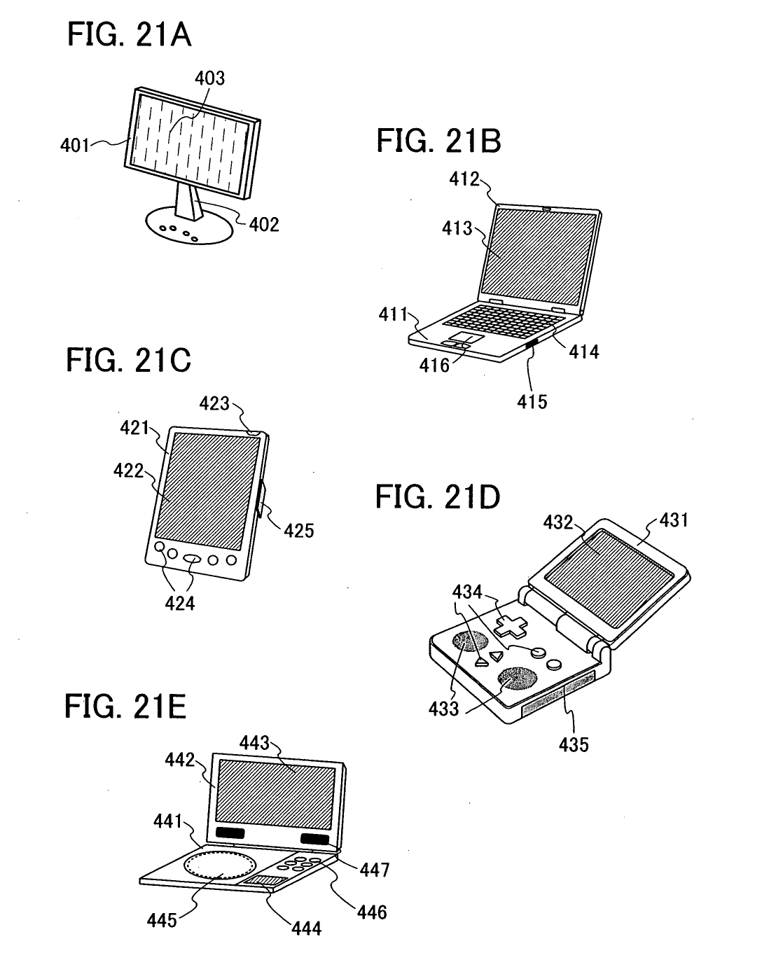

FIG. 21A shows an EL display, which includes a housing 401, a support 402, a display portion 403, and the like. The present invention is applicable to the display portion 403 with the use of the structures of the EL module shown in FIG. 15 and the display panel shown in FIG. 18.

By using the present invention, a favorable display with long life and high reliability can be obtained.

FIG. 21B shows a computer, which includes a main body 411, a housing 412, a display portion 413, a keyboard 414, an external connection port 415, a pointing device 416, and the like. The present invention is applicable to the display portion 413 with the use of the structures of the EL module shown in FIG. 15 and the display panel shown in FIG. 18.

By using the present invention, a favorable computer with long life and high reliability can be obtained.

FIG. 21C shows a portable computer, which includes a main body 421, a display portion 422, a switch 423, operation keys 424, an infrared port 425, and the like. The present invention is applicable to the display portion 422 with the use of the structures of the EL module shown in FIG. 15 and the display panel shown in FIG. 18.

By using the present invention, a favorable computer with long life and high reliability can be obtained.

FIG. 21D shows a portable game machine, which includes a housing 431, a display portion 432, a speaker portion 433, operation keys 434, a recording medium insert portion 435, and the like. The present invention is applicable to the display portion 432 with the use of the structures of the EL module shown in FIG. 15 and the display panel shown in FIG. 18.

By using the present invention, a favorable game machine with long life and high reliability can be obtained.

FIG. 21E shows a portable image reproduction device provided with a recording medium (specifically, a DVD player), which includes a main body 441, a housing 442, a first display portion 443, a second display portion 444, a recording medium reading portion 445, an operation key 446, a speaker portion 447, and the like. Note that the recording medium includes a DVD or the like.

The first display portion 443 mainly displays image information, while the second display portion 444 mainly displays character information. The present invention is applicable to the first display portion 443 and the second display portion 444 with the use of the structures of the EL module shown in FIG. 15 and the display panel shown in FIG. 18. Note that the image reproduction device provided with a recording medium includes a home game machine and the like.

By using the present invention, a favorable image reproduction device with long life and high reliability can be obtained.

For each display device used for the electronic equipment, a heat-resisting plastic substrate can also be used as well as a glass substrate depending on the size, strength, or the intended use, whereby further reduction in weight can be achieved.

Note that the examples shown in this embodiment are just examples, and the present invention it is not limited to these applications.

In addition, this embodiment can be implemented freely in combination with any description of the embodiment mode and the other embodiments.

The present invention can be used for a light-emitting device and a semiconductor device each using an EL element. Generation of gas or moisture is suppressed in a partition wall of the present invention, thereby an adverse effect on a light-emitting layer of an EL element can be prevented. Accordingly, a light-emitting device and a semiconductor device with long life and high reliability can be obtained.

This application is based on Japanese Patent Application Serial No. 2006-127012 filed in Japan Patent Office on 28, Apr. 2006, the entire contents of which are hereby incorporated by reference.

What is claimed is:

1. A method for manufacturing a light-emitting device, comprising the steps of:
forming a first electrode over a substrate;
forming a partition wall using a resin material over the substrate and the first electrode;
holding the partition wall for a first time period at a first temperature which is lower than a curing temperature of the resin material;
holding the partition wall for a second time period at a second temperature which is higher than the curing temperature of the resin material;
forming a light-emitting layer over the partition wall and the first electrode; and
forming a second electrode over the light-emitting layer.

2. The method for manufacturing the light-emitting device, according to claim 1, wherein the resin material is polyimide or polybenzoxazole.

3. The method for manufacturing the light-emitting device, according to claim 1, wherein the light-emitting layer is an organic compound.

4. The method for manufacturing the light-emitting device, according to claim 1, wherein the light-emitting layer is an inorganic compound.

5. The method for manufacturing the light-emitting device, according to claim 1, wherein the first temperature is 150° C. or higher and 200° C. or lower.

6. The method for manufacturing the light-emitting device, according to claim 1, wherein the second temperature is 300° C. or higher and 350° C. or lower.

7. A method for manufacturing a light-emitting device, comprising the steps of:
forming a first electrode over a substrate;
forming a resin material film over the substrate and the first electrode;
etching the resin material film to form a partition wall;
holding the partition wall for a first time period at a first temperature which is lower than a curing temperature of the resin material;
holding the partition wall for a second time period at a second temperature which is higher than the curing temperature of the resin material;
forming a light-emitting layer over the partition wall and the first electrode; and
forming a second electrode over the light-emitting layer.

8. The method for manufacturing the light-emitting device, according to claim 7, wherein the resin material is polyimide or polybenzoxazole.

9. The method for manufacturing the light-emitting device, according to claim 7, wherein the light-emitting layer is an organic compound.

10. The method for manufacturing the light-emitting device, according to claim 7, wherein the light-emitting layer is an inorganic compound.

11. The method for manufacturing the light-emitting device, according to claim 7, wherein the first temperature is 150° C. or higher and 200° C. or lower.

12. The method for manufacturing the light-emitting device, according to claim 7, wherein the second temperature is 300° C. or higher and 350° C. or lower.

13. The method for manufacturing the light-emitting device, according to claim 7, wherein the etching is dry etching.

14. The method for manufacturing the light-emitting device, according to claim 7, wherein the etching is wet etching.

15. A method for manufacturing a light-emitting device, comprising the steps of:
forming a thin film transistor, the thin film transistor comprising a semiconductor film and a gate electrode with a gate insulating film interposed therebetween
forming an interlayer insulating film over the thin film transistor;
forming a first electrode over the interlayer insulating film;
forming a partition wall using a resin material over the interlayer insulating film and the first electrode;
holding the partition wall for a first time period at a first temperature which is lower than a curing temperature of the resin material;
holding the partition wall for a second time period at a second temperature which is higher than the curing temperature of the resin material;
forming a light-emitting layer over the partition wall and the first electrode; and
forming a second electrode over the light-emitting layer.

16. The method for manufacturing the light-emitting device, according to claim 15, wherein the resin material is polyimide or polybenzoxazole.

17. The method for manufacturing the light-emitting device, according to claim 15, wherein the light-emitting layer is an organic compound.

18. The method for manufacturing the light-emitting device, according to claim 15, wherein the light-emitting layer is an inorganic compound.

19. The method for manufacturing the light-emitting device, according to claim 15, wherein the first temperature is 150° C. or higher and 200° C. or lower.

20. The method for manufacturing the light-emitting device, according to claim 15, wherein the second temperature is 300° C. or higher and 350° C. or lower.
